(19) United States
(12) Patent Application Publication
(10) Pub. No.: US 2017/0244872 A1
(43) Pub. Date: Aug. 24, 2017

(54) Camera Module Based on Molding Technique and Molded Circuit Unit and Manufacturing Method Thereof

(71) Applicant: NINGBO SUNNY OPOTECH CO., LTD., Ningbo (CN)

(72) Inventors: Mingzhu WANG, Ningbo (CN); Bojie ZHAO, Ningbo (CN); Takehiko TANAKA, Ningbo (CN); Feifan CHEN, Ningbo (CN); Liang DING, Ningbo (CN)

(21) Appl. No.: 15/058,109

(22) Filed: Mar. 1, 2016

(30) Foreign Application Priority Data
Feb. 18, 2016 (CN) 201610091489.7

(51) Int. Cl. H04N 5/225; H05K 3/28; H05K 3/30; H05K 1/18

(52) U.S. Cl. CPC H04N 5/2252; H04N 5/2253; H04N 5/2254; H04N 5/2257; H05K 1/181; H05K 3/284; H05K 3/30; H05K 2201/10151; H05K 2203/1327

(57) ABSTRACT

Molded circuit unit of camera module, based on molding technique, and manufacturing method thereof, includes a circuit board portion and a molding portion. The circuit board portion is electrically connected with a sensor of the camera module. The molding portion is molded to form on the circuit board portion to enclose electric elements protruded on the circuit board portion and support the camera lens of the camera module.

### NOTICE OF COPYRIGHT

A portion of the disclosure of this patent document contains material which is subject to copyright protection. The copyright owner has no objection to any reproduction by anyone of the patent disclosure, as it appears in the United States Patent and Trademark Office patent files or records, but otherwise reserves all copyright rights whatsoever.

### BACKGROUND OF THE PRESENT INVENTION

Field of Invention

The present invention relates to the field of camera module, and more particularly, to the camera module based on molding technique and the molded circuit unit and the manufacturing method thereof.

Description of Related Arts

Chip on Board (COB) technique is a very important technological process in camera module assembling and manufacturing processes. Structure of camera module based on conventional COB technical process is composed of parts including circuit board, sensor, lens holder, motor driver, and camera lens.

Referring to FIG. 1, it is a perspective view of a camera module manufactured with conventional COB technical process. The camera module includes a circuit board 1P, a photosensitive chip 2P, a holder 3P, an IR filter 4P, a motor driver 5P, and a camera lens 6P. The photosensitive chip 2P is mounted on the circuit board 1P. The optical filter 4P is mounted on the holder 3P. The camera lens 6P is mounted on the motor driver 5P. The motor driver 5P is mounted on the holder 3P. Therefore, the camera lens 6P is mounted above the photosensitive chip 2P.

It is worth mentioning that there are usually various circuit components 11P, such as resistors and capacitors, provided in the circuit board 1P. These circuit components 11P are protruded on the surface of the circuit board 1P, while the holder 3P also has to be mounted on the surface of the circuit board 1P and large enough in size of length, width and height to cover all these circuit components 11P protruded on the circuit board 1P. Therefore, in the conventional COB technique, there are disadvantages in assembling and cooperating work among the circuit board 1P, the circuit components 11P, and the holder 3P, that also, to a certain extent, restricts the development of camera module from being lighter, smaller and thinner.

Specifically, first of all, the circuit components 11P are directly exposed on the surface of the circuit board 1P that will unavoidably be influenced by the subsequent assembling process, such as the processes of affixing the holder 3P and soldering the motor driver 5P. Solder resist, dust and etc are easily be adhered on the circuit components 11P during soldering. Besides, the circuit components 11P and the sensor 2P are mutually connected within a space, so that the dusts and pollutants would easily adversely affect the photosensitive sensor 2P. Such influence may cause the assembled camera module having adverse effects like undesirable appearances and dark spots, resulting in a decrease of product yield rate.

In addition, the holder 3P is positioned at the outer side of the circuit components 11P, so that when installing the lens holder and the circuit board 1P, it is necessary to reserve a certain safety distance, in both the horizontal direction and the upward directly, between the holder 3P and the circuit component 11P, that not only substantially increases the horizontal size (length and width) and vertical size (thickness) of the camera module but also results in great difficulty in reducing the horizontal and vertical sizes of the camera module.

Thirdly, during the assembling process of the COB, the holder 3P is adhered on the circuit board 1P with adhesive material and the like glue. During such adhering process, an AA (Active Arrangement) technique is applied to adjust the central axis of the holder 3P, the circuit board 1P and the motor driver 5P, so as to achieve a coaxial condition in both the horizontal direction and vertical direction. Therefore, in order to satisfy the AA technique, plenty of glue has to be applied between the holder 3P and the circuit board 1P and between the lens holder and the motor driver 5P, while adjustment rooms are still required there between that substantially results in increasing the thickness of the camera module and the difficulty to the demand of thickness reduction of the camera model. On the other hand, such multiple adhering processes also cause tilt discrepancy in the assembling of the camera module easily while a higher flatness and smoothness requirement among the lens holder 3P, the circuit board 1P, and the motor driver 5P is desired.

In addition, in conventional COB technique, the circuit board IP is the most basic mounting and supporting tool for other components of the camera module, so that there is a definite requirement to the structural strength of the circuit board 1P itself, that requires the circuit board 1P to be made with a thicker thickness, and thus, on the other hand, rendering the camera module to have a certain thickness demand.

Along with the development of various electronic products and smart devices, camera modules further evolve to provide higher performance, lighter and thinner properties. Also, in order to meet various kinds of the developing demand in high performance aspect, including high resolution, high image quality and etc., more and more electronic components are used in the circuit while the chip becomes bigger and bigger, and passive components like driving resistors and capacitors relatively increase, which makes the scale of the electronic device become larger and larger, increases the difficult in assembling, and increases the overall size of the conventional camera module. In view of above, the conventional assemble method of the lens holder, the circuit board, and the circuit elements is substantially a great limitation and obstacle in developing and providing a more compact size camera module with lighter weight, smaller size and thinner thickness.

### SUMMARY OF THE PRESENT INVENTION

An object of the present invention is to provide a camera module with molded circuit unit, based on molding technique, and manufacturing method thereof, wherein the circuit unit includes a circuit board portion and a molding portion moldingly formed on the circuit board portion.

An object of the present invention is to provide a camera module with molded circuit unit, based on molding technique, and manufacturing method thereof, wherein the molded circuit unit includes at least a circuit element which is enclosed in a molding portion of the molded circuit unit without direct exposure to the outside environment.

An object of the present invention is to provide a camera module with molded circuit unit, based on molding technique, and manufacturing method thereof, wherein the circuit element(s) is integrally molded to be enclosed, cased and wrapped up in the molded circuit unit.

An object of the present invention is to provide a camera module with molded circuit unit, based on molding technique, and manufacturing method thereof, wherein the molded circuit unit includes a molding portion and a circuit board portion, wherein the molding portion is molded on the circuit board portion to cover, wrap and/or enclose the circuit element(s) of the molded circuit unit.

An object of the present invention is to provide a camera module with molded circuit unit, based on molding technique, and manufacturing method thereof, wherein the circuit board portion includes a main circuit board and a sensor, such as a photosensitive chip, which is provided on an inner surface of the circuit board and the molding portion is provided around the outer sides of the sensor.

An object of the present invention is to provide a camera module with molded circuit unit and manufacturing method thereof, wherein the main circuit board has an inner groove and the sensor is installed in the inner groove, so as to reduce the height of the molding portion as demanded.

An object of the present invention is to provide a camera module with molded circuit unit and manufacturing method thereof, wherein the main circuit board has an access adapted for the sensor to be installed from the back of the main circuit board with the photosensitive area of the sensor facing frontwardly, such that an easier installation method of invertedly installing the sensor is provided.

An object of the present invention is to provide a camera module with molded circuit unit and manufacturing method thereof, wherein an optical filter such as IR filter is installed in the inner opening of the access of the main circuit board, so that an extra site for installing the optical filter is not required.

An object of the present invention is to provide a camera module with molded circuit unit and manufacturing method thereof, wherein the main circuit board has at least at least a holding hole therein, wherein the molding portion fills and inserts into the holding hole, so as to enhance the bonding ability between the molding portion and the circuit board portion such that, correspondingly, the molding portion also enforces and strengthens the structure of the main circuit board.

An object of the present invention is to provide a camera module with molded circuit unit and manufacturing method thereof, wherein the molding portion provides a platform arranged for supporting the optical filter so as to provide an installation site for supporting the optical filter in position, so that no additional holder is required that substantially reduces the horizontal and vertical sizes of the molded circuit unit.

An object of the present invention is to provide a camera module molded circuit unit and manufacturing method thereof, wherein the molding portion is arranged for adaptable to install a driver and/or a camera lens in position thereon so as to replace and function as the conventional independent holder for supporting such driver or camera lens, such that an installation site for the driver and/or camera lens is provided and thus the overall size of the molded circuit unit is reduced.

An object of the present invention is to provide a camera module with molded circuit unit and manufacturing method thereof, wherein the molding portion substitutes the conventional holder, so that there is no need to additionally adhering process of the conventional holder or circuit board as usual while greatly increasing the accuracy of the art and manufacturing process of the camera module.

An object of the present invention is to provide a camera module with molded circuit unit and manufacturing method thereof, wherein the camera module is assembled from the molded circuit unit such that camera module with smaller size and thinner thickness and better performance can thus be achieved.

An object of the present invention is to provide a camera module with molded circuit unit and manufacturing method thereof, wherein the assemble of the camera module is manufactured by means of molding based on molding technique that effectively improves the conventional COB technique for the camera module.

An object of the present invention is to provide a camera module with molded circuit unit and manufacturing method thereof, wherein molding technique is applied to manufacture the circuit unit to obtain the molded and integrated circuit unit according to the present invention.

In order to accomplish the above objects of the present invention as well as other objects and advantages of the present invention, the present invention, in one aspect, the present invention provides a molded circuit unit, which includes a circuit board portion for electrically connecting a sensor, such as a photosensitive chip, of the camera module, and a molding portion which is moldingly formed on the circuit board portion.

According to one embodiment of the present invention, the circuit board portion of the molded circuit unit includes a main circuit board, wherein the molding portion is integrally and moldingly connected to the main circuit board. According to a preferred embodiment of the present invention, the circuit board portion of the molded circuit unit includes at least one circuit element protruded on the main circuit board and the circuit element is enclosed and wrapped up by molding portion.

According to one embodiment of the present invention, the sensor of the molded circuit unit is adapted to be installed on an upper surface of the main circuit board while the molding portion is provided around the outer sides of the sensor.

According to one embodiment of the present invention, the main circuit board of the molded circuit unit has an inner groove and the sensor is installed in the inner groove.

According to one embodiment of the present invention, the main circuit board of the molded circuit unit has an access provided therein enabling the sensor to be installed from the back of the main circuit board at the access with the photosensitive area of the sensor exposed frontwardly through the access.

According to one embodiment of the present invention, the access of the molded circuit unit is a step shaped access so as to provide a stable installation site for the sensor.

According to one embodiment of the present invention, the main circuit board of the molded circuit unit has one or more holding holes provided therein, wherein the molding portion fills and inserts into the holding holes so as to enhance the bonding ability between the molding portion and the main circuit board such that, correspondingly, the molding portion also enforces and strengthens the structure of the main circuit board.

According to one embodiment of the present invention, the molding portion of the molded circuit unit protrudingly surrounds around the outer sides of the sensor.

According to one embodiment of the present invention, the molding portion of the molded circuit unit provides a platform, wherein the platform forms an inner groove adaptable to support and connect an optical filter of the camera module.

According to one embodiment of the present invention, the material of the main circuit board of the molded circuit unit is selected from the group consisting of rigid-flex board, ceramic substrate, and rigid PCB.

According to one embodiment of the present invention, the material of the molding portion of the molded circuit unit is selected from the group consisting of nylon, LCP (Liquid Crystal Polymer), PP (Polypropylene), and resin.

According to one embodiment of the present invention, the molding technique to be applied in the molding portion of the molded circuit unit includes insert molding or die molding.

In one embodiment of the present invention, a manufacturing method of molded circuit unit is provided, which includes the step of moldingly form a mold portion on a main circuit board.

In one embodiment of the present invention, the manufacturing method of molded circuit unit includes the step of moldingly enclosing at least a circuit element protruded on the main circuit board by a molding portion.

In one embodiment of the present invention, the manufacturing method of the molded circuit unit includes the step of providing in the main circuit board an inner groove adapted for installing a sensor such as a photosensitive chip.

In one embodiment of the present invention, the manufacturing method of the molded circuit unit includes the step of providing in the main circuit board an access adapted for a sensor, such as a photosensitive chip, to be installed from the back of the main circuit board.

In one embodiment of the present invention, the manufacturing method of the molded circuit unit includes the step of providing a holding hole at the molding area of the main circuit board before the moldingly forming step of the molding portion.

Another aspect of the present invention provides a camera module, which includes a molded circuit unit, a camera lens and a sensor, wherein the camera lens is positioned along the photosensitive path of the sensor and the sensor is electrically connected with the molded circuit unit.

In one embodiment of the present invention, the camera module includes a frame which is provided on the molded circuit unit, and the camera lens is provided on the frame.

In one embodiment of the present invention, the camera module includes a driver, wherein the camera lens is provided on the driver and the driver is provided on the molded circuit unit.

In one embodiment of the present invention, the camera module includes an optical filter provided on the molded circuit unit.

In one embodiment of the present invention, the camera module includes an optical filter provided on the frame.

Still further objects and advantages will become apparent from a consideration of the ensuing description and drawings.

These and other objectives, features, and advantages of the present invention will become apparent from the following detailed description, the accompanying drawings, and the appended claims.

### BRIEF DESCRIPTION OF THE DRAWINGS

FIG. 1 is a sectional view of a camera module illustrating the conventional COB packaging technique.

FIG. 2 is a sectional perspective view of a camera module according to a first preferred embodiment of the present invention.

FIG. 3 is an exploded perspective view of the camera module according to the above first preferred embodiment of the present invention.

FIG. 4 is a partially enlarged perspective view of the camera module according to the above first preferred embodiment of the present invention.

FIG. 5 is a schematic perspective view illustrating a moldingly forming process of molding circuit unit of the camera module according to the above first preferred embodiment of the present invention.

FIG. 6A is a sectional view of a molded circuit unit of the camera module according to a first alternative mode of the above first preferred embodiment of the present invention.

FIG. 6B is a partially enlarged sectional view illustrating the molded circuit unit of the camera module according to the above first alternative mode of the first preferred embodiment of the present invention.

FIG. 7A is a sectional view of a molded circuit unit of the camera module according to a second alternative mode of the above first preferred embodiment of the present invention.

FIG. 7B is a partially enlarged section view of the circuit unit of the camera module according to the above second alternative model of the first preferred embodiment of the present invention.

FIG. 8A is a sectional view of a circuit unit of the camera module according to a third alternative mode of the above first preferred embodiment of the present invention.

FIG. 8B is a partially enlarged sectional view of the circuit unit of the camera module according to the above third alternative mode of the first preferred embodiment of the present invention.

FIG. 9 is a sectional view of a camera module according to a second preferred embodiment of the present invention.

FIG. 10 is an exploded perspective view of the camera module according to the above second preferred embodiment of the present invention.

FIG. 11 is a partially enlarged view of the camera module according to the above second preferred embodiment of the present invention.

FIG. 12 is a sectional perspective view of a camera module according to a third preferred embodiment of the present invention.

FIG. 13 is a perspective view illustrating a moilingly forming process of molding circuit unit of the camera module according to the above third preferred embodiment of the present invention.

FIG. 14 is a sectional view of a camera module according to a fourth preferred embodiment of the present invention.

FIG. 15 is an exploded view of the camera module according to the above fourth preferred embodiment of the present invention.

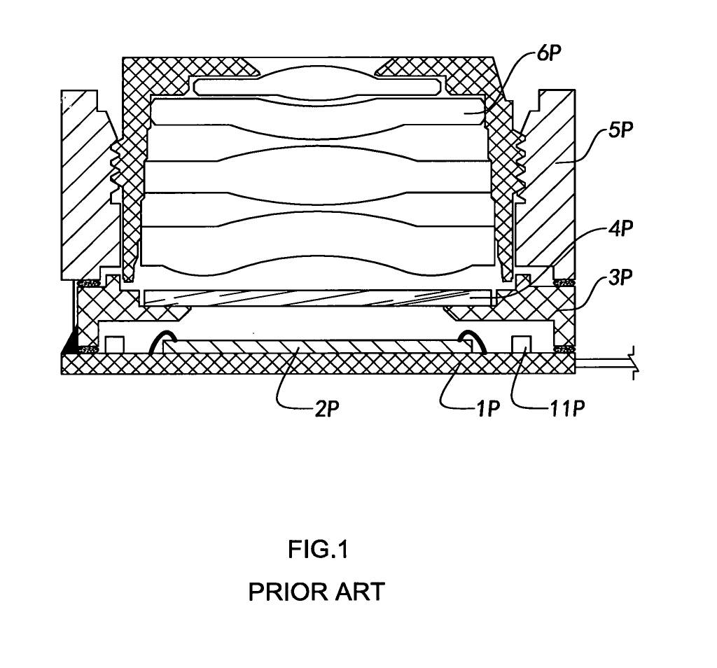

### DETAILED DESCRIPTION OF THE PREFERRED EMBODIMENT

The following description is disclosed to enable any person skilled in the art to make and use the present invention. Preferred embodiments are provided in the following description only as examples and modifications will be apparent to those skilled in the art. The general principles defined in the following description would be applied to other embodiments, alternatives, modifications, equivalents, and applications without departing from the spirit and scope of the present invention.

The following is disclosed in order that those skilled in the art can implement the present invention. Preferred embodiments in the following descriptions are to give examples only. Those skilled in the art can think of other obvious modifications. The basic notions of the present invention defined in the following descriptions can apply to other implementations, modifications, improvements, equivalences, and other technical solutions that do not deviate the scope or spirit of the present invention.

Those skilled in the art should understand that, in the disclosure of the present invention, terminologies of “longitudinal,” “lateral,” “upper,” “front,” “back,” “left,” “right,” “perpendicular,” “horizontal,” “top,” “bottom,” “inner,” “outer,” and more that indicate relations of direction or position are based on the relations of direction or position shown in the appended drawings, which is only for ease of describing the present invention and simplifying the description, rather than to indicate or imply that the referred device or element has to apply specific direction or to be operated or structured in specific direction. Therefore, the above mentioned terminologies shall not be interpreted as confine to the present invention.

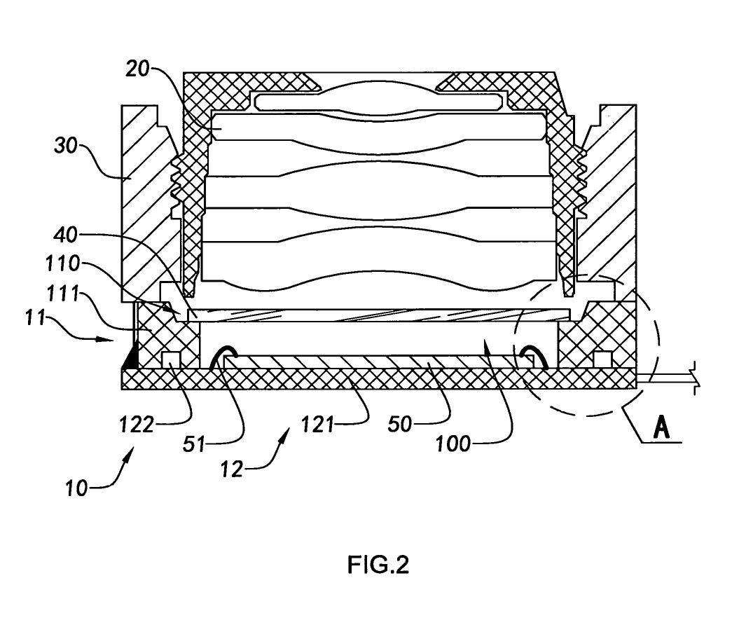

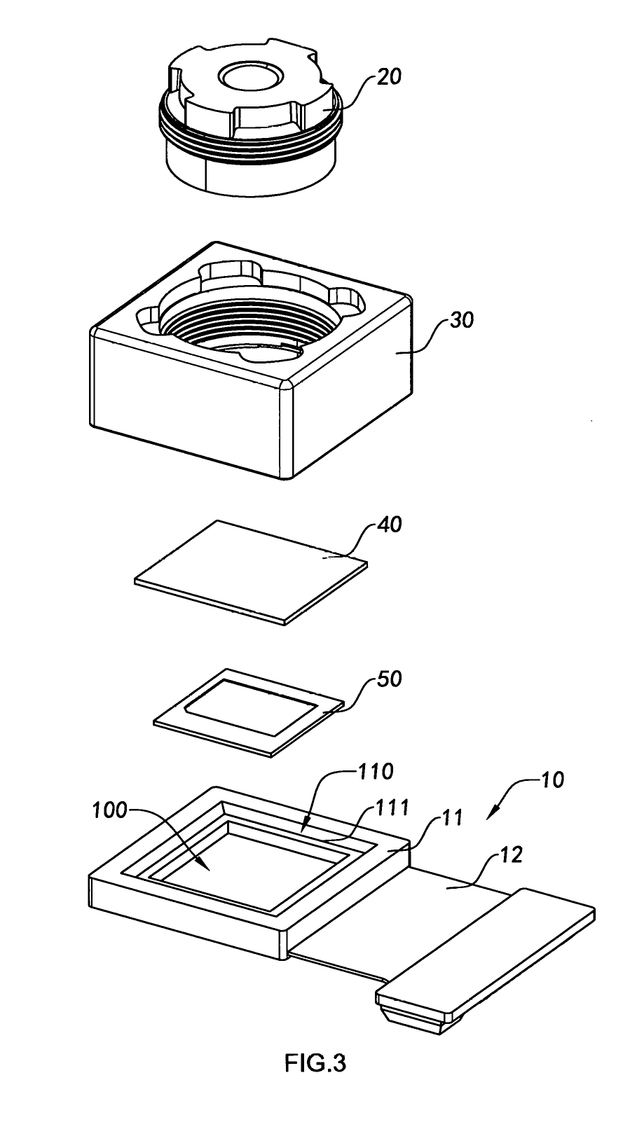

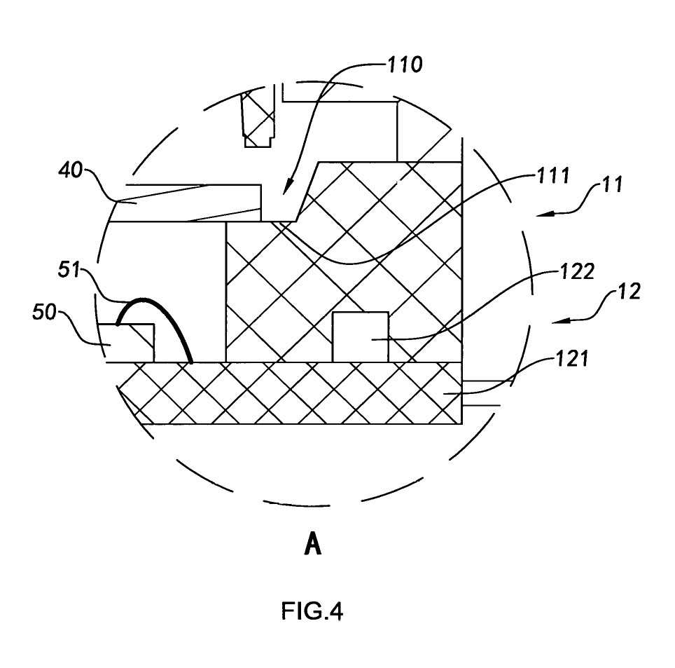

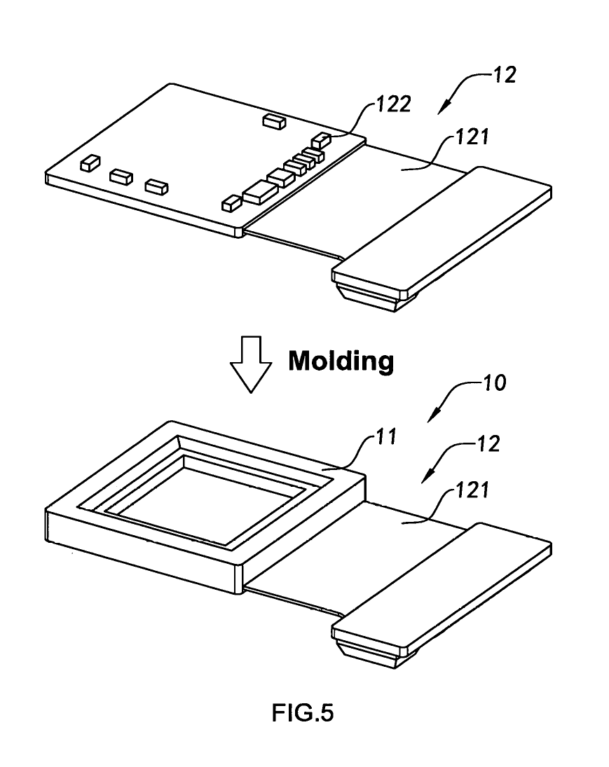

Referring to FIGS. 2-5, a camera module according to a first preferred embodiment of the present invention is illustrated. The camera module can be a moving focal camera module, which includes a molded circuit unit 10, a camera lens 20, a driver 30 such as a motor, and a sensor 50.

The driver 30 is installed on the molded circuit unit 10, wherein the camera lens 20 is installed on the driver 30, and thus the camera lens 20 is supported above the molded circuit unit 10.

Further, the molded circuit unit 10 includes a molding portion 11 and a circuit board portion 12, wherein the molding portion 11 is molded and connected with the circuit board portion 12.

The circuit board portion 12 includes a main circuit board 121, wherein the sensor 50 is provided on the main circuit board 121 and positioned at the inner side of the molding portion 11.

Specifically, the driver 30 is installed on the molding portion 11 of the molded circuit unit 10 and electrically connected with the circuit board portion 12, wherein the camera lens 20 is installed on the driver 30 which is adapted for autofocusing the camera lens 20. The camera lens 20 is positioned along a photosensitive path of the sensor 50, so that when the camera module is capturing image of an object, light reflected from the object can be processed by the camera lens 20 and then received by the sensor 50 for photoelectric conversion.

Further, the circuit board portion 12 includes a photosensitive circuit (not shown in the figures) and at least one circuit element 122. The photosensitive circuit is precontained in the main circuit board 121, wherein the circuit element 122 is electrically connected with the photosensitive circuit and the sensor 50 to provide for processing photosensitive operation of the sensor 50. The circuit element 122 can be, for example but not limited to, a resistor, a capacitor, a diode, a triode, a potentiometer, or an electric relay.

Particularly, in one embodiment of the present invention, when the camera module is being assembled, the driver 30 is electrically connected to the photosensitive circuit through a conductive wire which is soldered to the main circuit board 121.

It is worth mentioning that the molding portion 11 can enclose and wrap up the circuit element 122 therein, so that the circuit element 122 will not be directly exposed in outer space, and more particularly, the circuit element 122 will not be exposed in an enclosed environment that communicates with the sensor 50. This is substantially different from the conventional camera module that its circuit elements are exposed on the circuit board. Accordingly, the circuit element 122, such as resistance-capacitance components, is prevented from any dust and sundries staying on the circuit element 122 and polluting the sensor 50 of the present invention. The molding portion 11 has an opening 100 rendering the molding portion 11 being positioned surround the outer sides of the sensor 50 and providing a light path between the camera lens 20 and the sensor 50.

It is worth mentioning that the enclosure of the circuit element 122 by the molding portion 11 contains advantages in protecting the circuit element 122, and other corresponding conveniences to the camera module. However, according to the present invention, it should be understood to person who skilled in the art should that the molding portion 11 is not only limited in fully enclosing and wrapping up one or more the circuit elements 122 and even the lead wire 51 electrically connecting the sensor 50 and the main circuit board 121. In other words, in other embodiments of the present invention, the molding portion 11 may be directly molded on a circuit board 12 having no protruding circuit element 122, or be molded at different positions including the outer side and the periphery of the circuit element 122.

It is worth mentioning that, in one embodiment of the present invention, the molding portion 11 protrudingly surrounds the outer side of the sensor 50. More particularly, the molding portion 11 can be an integral casing body that provides good sealing ability, so that when the driver 30 is installed on the molding portion 11, the sensor 50 is concealed in a sealed inner space between the driver 30, the molding portion 11 an the main circuit board 121.

Specifically, during the manufacturing of the molded circuit unit, the main circuit board 121, that can be a traditional circuit board, is processed with molding on the surface thereof. For example, a circuit board that has been treated with Surface Mount Technology (SMT) can be molded to form the molding portion 11 by insert molding with such as an injection molding machine, or that the molding portion 11 can be formed by die molding (pressing molding) technique that is commonly used in semiconductor packaging. The main circuit board 121 can be, for example, but not limited to, a rigid-flex board, a ceramic substrate (without flexible board), a rigid PCB (without flexible board), and etc. The molding portion 11 can be formed by a molding method selected from, for example but not limited to, injection molding, insert molding, die molding, pressing molding, and etc. The material of the molding portion 11 can be, for example but not limited to, nylon, LCP (Liquid Crystal Polymer), or PP (Polypropylene) for injection molding or insert molding, and resin for die molding or pressing molding. Those skilled in the art should understand that the above recited manufacturing methods and optional materials are just to give examples to illustrate implementations of the present invention, rather than to limit the present invention.

It is also worth mentioning that the driver 30 is installed on the molding portion 11 of the circuit unit 10, so that the molding portion 11 itself also serves a frame to support and hold the driver 30 in position to function as the independent motor mounting holder of a conventional camera module with a different assembling process than the conventional COB manufacturing method. In the conventional COB manufacturing method, the independent motor mounting holder of the camera module is adhered on the circuit board. However, the molding portion 11 of the present invention is provided on the main circuit board 121 by means of molding technique that does not require any adhering and affixing process therefor. The present molding method, with respect to the conventional adhering method, has better connection stability and controllability of process, and that no gluing space is required to be reserved for AA adjustment between the molding portion 11 and the main circuit board 121, that further reduces the adhering space for the AA adjustment of the conventional camera module, such that the thickness of camera module can be decrease accordingly. Meanwhile, the electric elements 122 are enclosed and wrapped by the molding portion 11 that allows the electric elements and the supporting function being overlappedly arranged and provided, and has no need to reserve any safety space for the electric elements as required by the conventional camera module. Therefore, a height of the molding portion 11 that can also function as a traditional supporting holder can be provided in a smaller and more compact manner, so as to further provide room to reduce the thickness of camera module. In addition, the replacement of the traditional independent mounting holder with the molding portion 11 of the present invention avoids tilt error caused in the affixing and assembling of conventional mounting holder and reduces accumulated tolerance of the assembling of the camera module.

Furthermore, the molding portion 11 includes a platform 111 which is adapted for installing an optical filter 40 such as IR filter thereon, ensuring the optical filter 40 to be provided above the sensor 50. In other words, light entered the camera lens 20 reaches the sensor 50 after the function of the optical filter 40. The optical filter 40 can be embodied as, for example but not limited to, a IR-Cut Filter (IRCF).

The platform 111 of the molding portion 11 has an inner groove 110 providing adequate space to install the optical filter 40. It is worth mentioning that the molding portion 11, which substitutes traditional mounting holder, connects the driver 30 with the optical filter 40 and provides installation space for the optical filter 40, so that the molding portion 11, the optical filter 40 and the circuit element 122 are reasonably arranged, that fully employs the remaining space outside the photosensitive area of the sensor 50 so as to minimize the size of the camera module. Also, by means of the molding technique, a flat and smooth platform 111 of the molding portion 11 is provided that enables the optical filter 40 to be evenly and flatly installed to ensure the consistency of light path.

More specifically, the inner groove 110 is a step groove having a L-ring shape and communicates with the opening 100 of the molding portion 11, so that the optical filter 40 can be supported and installed along the photosensitive path of the sensor 50.

According to this embodiment of the present invention, the sensor 50 is electrically connected with the main circuit board 121 through a series of lead wire 51, and electrically connected with the photosensitive circuit. The lead wires 51 can be embodied as, for example but not limited to, gold wire, copper wire, aluminum wire, or silver wire. Particularly, the lead wires 51 of the sensor 50 can be connected with the main circuit board 121 through conventional COB method, for example but not limited to, welding and soldering. It is worth mentioning that the lead wires 51 may also be treated as electric element in the present invention that would also be enclosed and cased by the molding portion. In other words, the connection between the sensor 50 and the main circuit board 121 may use current connection means to reduce the improvement cost of technology, to full apply the conventional art and equipments, and to avoid the waste of resources. Without doubt, those skilled in the art should be able to understand that the connection between the sensor 50 and the main circuit board 121 may also be embodied as any other connection way that is able to achieve the object of the present invention, wherein the present invention is not confined in this regard.

It is worth mentioning that in this embodiment of the present invention, the sensor 50 is provided on the upper surface of the main circuit board 121, wherein the molding portion 11 is positioned surrounding the outer side of the sensor. During the manufacturing of the molded circuit unit, various orders of the manufacturing steps can be selected, for example but not limited to that, in one embodiment, the sensor 50 can be installed on the main circuit board 121 first, and then the molding portion 11 is moldingly formed at the outer sides of the sensor 50 and at the peripheral edges of the main circuit board 121 to enclose, case and/or wrap up the circuit elements 122 protruded from the main circuit board 121 therein. In an alternative mode of the present invention, the peripheral edges of the main circuit board 121 can be molded to form the molding portion 11 to enclose, case and/or wrap up the circuit elements 122 protruded from the main circuit board 121 therein first, and then the sensor 50 is installed on the main circuit board 121 and surrounded by the inner sides of the molding portion 11.

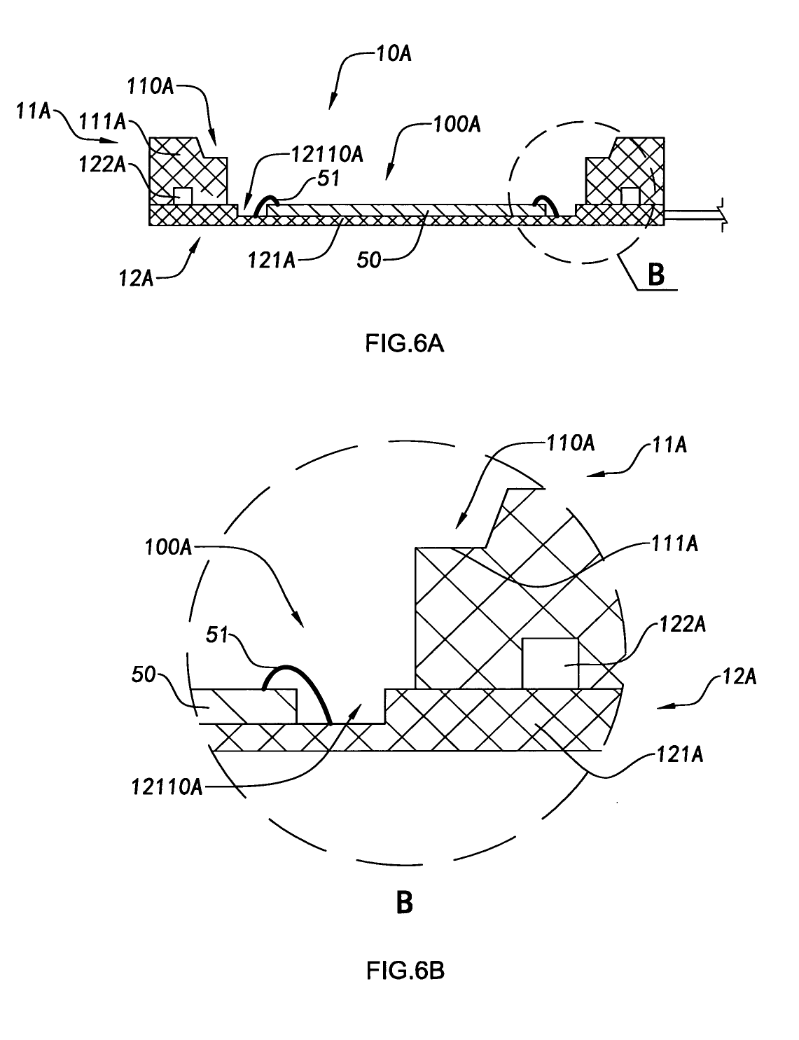

FIGS. 6A and 6B illustrate a molded circuit unit of the camera module according to a first alternative mode of the first preferred embodiment of the present invention. The molded circuit unit 10A includes a molding portion 11A and a circuit board portion 12A, wherein the molding portion 11A is molded to connect with the circuit board portion 12A.

The circuit board portion 12A includes a main circuit board 121A, wherein the sensor 50 is provided on the main circuit board 121A and positioned at the inner side of the molding portion 11A.

Specifically, the driver 30 is installed on the molding portion 11A of the molded circuit unit 10A and electrically connected with the circuit board portion 12A, wherein the camera lens 20 is installed on the driver 30 which is adapted for autofocusing the camera lens 20. The camera lens 20 is positioned along a photosensitive path of the sensor 50, so that when the camera module is capturing image of an object, light reflected from the object can be processed by the camera lens 20 and then received by the sensor 50 for photoelectric conversion.

Further, the circuit board portion 12A includes a photosensitive circuit and at least one circuit element 122A. The photosensitive circuit is built in the main circuit board 121A, wherein the circuit element 122A is electrically connected with the photosensitive circuit and the sensor 50 to provide for processing photosensitive operation of the sensor 50. The circuit element 122A can be, specifically but not limited to, a resistor, a capacitor, a diode, a triode, a potentiometer, or an electric relay.

Particularly, in one embodiment of the present invention, when the camera module is being assembled, the driver 30 is electrically connected to the photosensitive circuit through a conductive wire which is soldered to the main circuit board 121.

It is worth mentioning that the molding portion 11A enclose, case and/or wrap up the circuit element 122A therein, so that the circuit element 122A will not be directly exposed in outer space, and more particularly, the circuit element 122 will not exposed in an enclosed environment that communicates with the sensor 50. This is substantially different from the conventional camera module that its circuit elements are exposed on the circuit board. Accordingly, the circuit element 122A, such as resistance-capacitance components, is prevented from any dust and sundries staying on the circuit element 122A and polluting the sensor 50. The molding portion 11A has an opening 100A provided therein, rendering the molding portion 11A being positioned around the outer sides of the sensor 50 and providing a light path between the camera lens 20 and the sensor 50.

Further, the main circuit board 121A has an inner groove 12110A, wherein the sensor 50 is installed in the inside of the inner groove 12110A. Unlike the molded circuit unit of 10 the above first preferred embodiment, the main circuit board 121A has the inner groove 12110A indented thereon to accommodate the sensor 50 to be received therein, so that the sensor 50 is prevented to significantly protrude from the uppermost surface of the main circuit board 121A, so as to lower the depth of the sensor 50 with respect to the molding portion 11A, so as to reduce a height limit of the molding portion 11A caused by the sensor 50 to further provide a possibility of further reduction of the height of the molding portion 11A.

Specifically, during the manufacturing of the molded circuit unit, the main circuit board 121A, that can be a traditional circuit board, is processed with molding on the surface thereof. For example, a circuit board that has been treated with Surface Mount Technology (SMT) can be molded to form the molding portion 11A by insert molding with such as an injection molding machine, or that the molding portion 11A can be formed by die molding or pressing molding technique that is commonly used in semiconductor packaging. Particularly, in one embodiment, the inner groove 12110A is firstly be made on the main circuit board 121A. In other words, the inner groove 12110A is made on a traditional main circuit board adapted for accommodating and installing the sensor 50. The main circuit board 121A can alternatively be, for example but not limited to, a rigid-flex board, a ceramic substrate (without flexible board), a rigid PCB (without flexible board), and etc. The molding portion 11A can be formed by a molding method selected from, for example but not limited to, injection moulding, insert molding, die molding, pressing molding, and etc. The material of the molding portion 11A can be, for example but not limited to, nylon, LCP (Liquid Crystal Polymer), or PP (Polypropylene) for injection molding or insert molding, and resin for die molding or pressing molding. Those skilled in the art should understand that the above possible manufacturing methods and optional materials are just to give examples to illustrate implementations of the present invention, rather than to limit the present invention

It is also worth mentioning that the driver 30 is installed on the molding portion 11A of the circuit unit 10A, so that the molding portion 11A is also arranged to serve the function of the motor mounting holder of a conventional camera module that can substantially support and hold the driver 30 in position, so that the molded portion 11A enables the camera module with molded circuit unit 10A to be assembled in a different process with respect to the conventional COB manufacturing method. In the conventional COD manufacturing method, the independent motor mounting holder is adhered on the circuit board. However, the molding portion 11A of the present invention is provided on the main circuit board 121A by means of molding technique that does not require any adhering and affixing process therefor. The present molding method with respect to the conventional adhering method, has better connection stability and controllability of process, and that no gluing space is required to be reserved for AA adjustment between the molding portion 11A and the main circuit board 121A, that further reduces the adhering space for the AA adjustment of the conventional camera module, such that the thickness of the camera module can be decreased accordingly. In addition, the electric elements 122A are enclosed, cased and/or wrapped by the molding portion 11A that allows the electric elements 122A and the supporting function being overlappedly arranged and provided, and has no need to reserve any safety space for the electric elements as required by the conventional camera module. Therefore, the height of the molding portion 11A that can also function as a supporting or mounting holder can be provided in a smaller and more compact manner, so as to further provide room to reduce the thickness of camera module. In addition, the replacement of the traditional mounting holder frame with the molding portion 11A of the present invention avoids tilt error caused in the affixing and assembling of conventional mounting holder, and reduces accumulated tolerance of the assembling of the camera module.

Moreover, the molding portion 11A includes a platform 111A, which is adapted for installing the optical filter 40 thereon, so as to ensure the optical filter 40 to be provided above the sensor 50. In other words, light entered the camera lens 20 reaches the sensor 50 after the function of the optical filter 40. The optical filter 40 can be embodied as, for example but not limited to, a IR-Cut Filter (IRCF).

The platform 111A of the molding portion 11A has a ring shaped inner groove 110A providing adequate space to install the optical filter 40. It is worth mentioning that the molding portion 11, which substitutes the traditional mounting holder, connects the driver 30 with the optical filter 40 and provides installation space for the optical filter 40, so that the molding portion 11A, the optical filter 40 and the circuit element 122A are reasonably arranged, that fully employs the remaining space outside of the photosensitive area of the sensor 50 so as to minimize the size of the camera module. Also, by means of the molding technique, a flat and smooth platform 111A of the molding portion 11A is provided that enables the optical filter 40 to be evenly and flatly installed to ensures the consistency of light path.

More specifically, the inner groove 110A has a L-ring shaped cross section and is communicated with the opening 100A of the molding portion 11A, so that the optical filter 40 can be supported and installed along the photosensitive path of the sensor 50.

According to this embodiment of the present invention, the sensor 50 is electrically connected with the main circuit board 121A through a series of lead wire 51A, and electrically connected with the photosensitive circuit. The lead wires 51A can be embodied as, for example but not limited to, gold wires, copper wires, aluminum wires, or silver wires. Particularly, the lead wires 51 of the sensor 50 can be connected with the main circuit board 121A through conventional COB method, for example but not limited to, welding or soldering. In other words, the connection between the sensor 50 and the main circuit board 121A may use current connection means to reduce the improvement cost of technology, to fully apply the conventional art and equipments, and to avoid the waste of resources. Without doubt, those skilled in the art should be able to understand that the connection between the sensor 50 and the main circuit board 121A may also be embodied as any other connection way that is able to achieve the object of the present invention, wherein the present invention is not confined in this regard.

It is worth mentioning that in this embodiment of the present invention, the sensor 50 is provided in the inner groove 12110A of the main circuit board 121A, wherein the molding portion 11A is positioned surrounding the outer sides of the sensor 50. During the manufacturing of the molded circuit unit, various orders of the manufacturing steps can be selected, for example but not limited to that, in one embodiment, the inner groove 12110A can be provided on the main circuit board 121A first, so that the sensor 50 can be installed in the inner groove 12110A of the main circuit board 121A, and then the molding portion 11A is molded around the outer sides of the sensor 50 and at the peripheral edges of the main circuit board 121A to enclose, case and/or wrap up the circuit elements 122A protruded from the main circuit board 121A therein. In an alternative mode of the first preferred embodiment of the present invention, the inner groove 12110A can be made in the main circuit board 121A first, and then the peripheral edges of the main circuit board 121A can be molded to form the molding portion 11A to enclose, case and/or wrap up the circuit elements 122A protruded from the main circuit board 121A therein. Then the sensor 50 is installed in the inner groove 12110A of the main circuit board 121A to be positioned within the inner sides of the molding portion 11A.

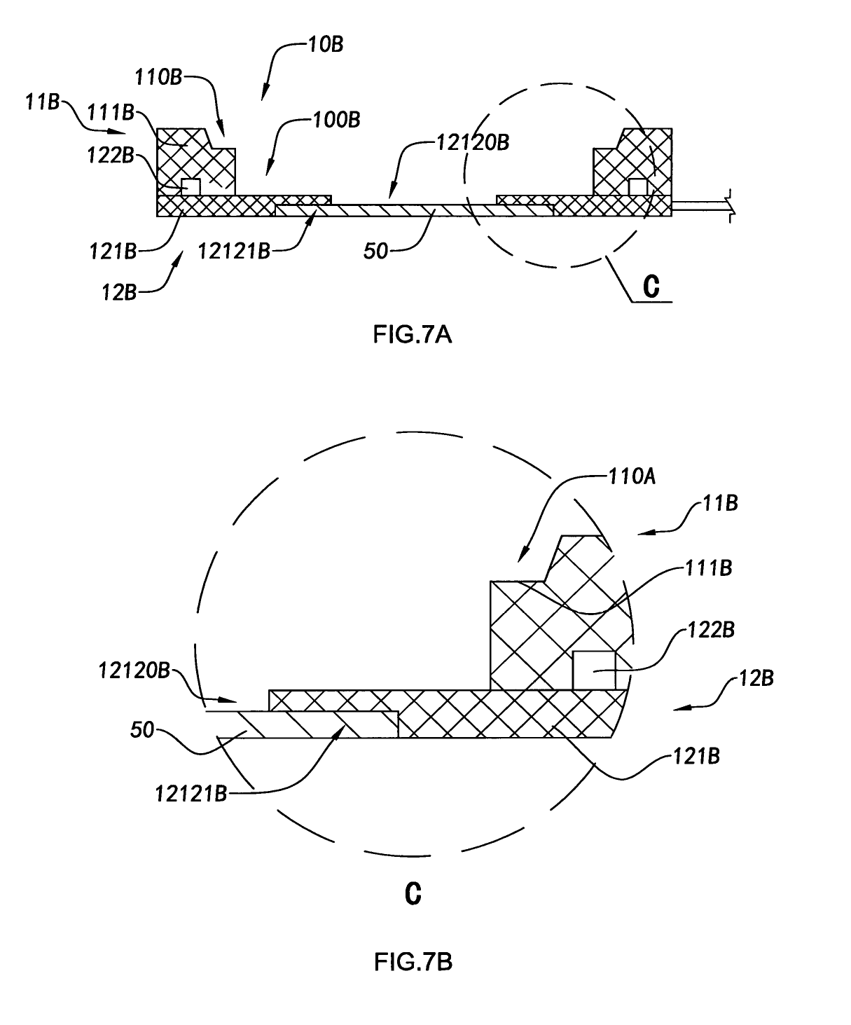

FIGS. 7A and 7B illustrates a molded circuit unit of the camera module according to a second alternative mode of the above first preferred embodiment of the present invention. The molded circuit unit 10B includes a molding portion 11B and a circuit board portion 12B, wherein the molding portion 11B is moldingly connected to the circuit board portion 12B.

The circuit board portion 12B includes a main circuit board 121B, wherein the sensor 50 is installed on the main circuit board 121B and positioned at the inner side of the molding portion 11B.

Specifically, the driver 30 is installed on the molding portion 11B of the molded circuit unit 10B and electrically connected with the circuit board portion 12B, wherein the camera lens 20 is installed on the driver 30 which is adapted for autofocusing the camera lens 20 by the driver 30. The camera lens 20 is positioned along a photosensitive path of the sensor 50, so that when the camera module is capturing image of an object, light reflected from the object can be processed by the camera lens 20 and then received by the sensor 50 for photoelectric conversion.

Further, the circuit board portion 12B includes a photosensitive circuit (not shown in the figures) and at least one circuit element 122B. The photosensitive circuit is preinstalled in the main circuit board 121B, wherein the circuit element 122B is electrically connected with the photosensitive circuit and the sensor 50 to provide for processing photosensitive work of the sensor 50. The circuit element 122B can be, for example but not limited to, a resistor, a capacitor, a diode, a triode, a potentiometer, or an electric relay.

Particularly, in one embodiment of the present invention, when the camera module is being assembled, the driver 30 is electrically connected to the photosensitive circuit through a conductive wire which is soldered on the main circuit board 121B.

It is worth mentioning that the molding portion 11B can enclose, case and/or wrap up the circuit element 122B therein, so that the circuit element 122B will not be directly exposed in outer space, and more particularly, the circuit element 122B will not exposed in an enclosed environment that communicates with the sensor 50. This is substantially different from the conventional camera module that its circuit elements are exposed on the circuit board of conventional camera module. Accordingly, the circuit element 122B, such as resistance-capacitance components, is prevented from any dust and sundries staying on the circuit element 122B and polluting the sensor 50. The molding portion 11B has an opening 100B wherein the molding portion is positioned surrounding the outer sides of the sensor 50 and providing a light path between the camera lens 20 and the sensor 50.

Further, the main circuit board 121B has an access 12120B provided therein, wherein a lower part of the access 12120B is adaptable for installation of the sensor 50. The access 12120B communicates the upper and lower sides of the main circuit board 121B, so that when the sensor 50 is installed on the main circuit board 121B from the back of the main circuit board 121B with the photosensitive area of the sensor 50 facing up, the photosensitive area of the sensor 50 can receive incoming light from the camera lens 20.

Further, the access 12120B has a ring shaped outer groove 12121B to provide an installation site for the sensor 50. Particularly, as the sensor 50 being installed in the outer groove 12121B, the upper surface of the sensor 50 is aligned with the surface of the main circuit board 121B at the same plane so as to ensure an evenness and smoothness surface of the molded circuit unit 10B.

In one embodiment of the present invention, the access 12120B has a step shaped cross section to facilitate the installation of the sensor 50 and provide a stable installation site for the sensor 50, while providing the photosensitive area of the sensor 50 be disposed in an inner space.

It is worth mentioning that this embodiment of the present invention provides a kind of chip installation method, i.e. the flip chip (FC) method, that differs from conventional. The sensor 50 is installed on the main circuit board 121B from a reverse direction of the main circuit board 121B, which is different from the above embodiment that requires installation on the main circuit board 121 from the front side of the main circuit board 121, that is from the upper side of the main circuit board 121 with the photosensitive area of the sensor 50 facing upwards. This kind of structure and way of installation allows the sensor 50 and the molding portion 11B to be relatively independent. Installation of the sensor 50 will not be affected by the molding portion 11B. Molding of the molding portion 11B also makes less impact to the sensor 50. Besides, the sensor 50 is embedded in the outer side of the main circuit board 121B without protruding to the inner side of the main circuit board 121B, so as to leave a larger space in the inner side of the main circuit board 121B, such that the height of the molding portion 11B will not be limited by the height of the sensor 50 that allows the molding portion 11B to achieve a smaller height.

Specifically, during the manufacturing of the molded circuit unit, a conventional circuit board may be used as the main circuit board 121B and the molding is conducted on the surface of the main circuit board 121B. For example, a circuit board that has been treated with Surface Mount Technology (SMT) can be molded to form the molding portion 11B by insert molding with an injection molding machine, or that the molding portion 11B can be formed by die molding and pressing molding technique that is commonly used in semiconductor packaging, as well as to provide the access 12120B in the main circuit board 121B. The main circuit board 121B can alternatively be, for example but not limited to, a rigid-flex board, a ceramic substrate (without flexible board), a rigid PCB (without flexible board), and etc. The molding portion 11B can be formed by a molding method selected from, for example but not limited to, injection moulding, insert molding, die molding, pressing molding, and etc. The material of the molding portion 11B can be, for example but not limited to, nylon, LCP (Liquid Crystal polymer), or PP (Polypropylene) for injection molding or insert molding, and resin for die molding or pressing molding. Those skilled in the art should understand that the above recited manufacturing methods and optional materials are just to give examples to illustrate implementations of the present invention, rather than to limit the present invention.

It is also worth mentioning that the driver 30 is installed on the molding portion 11B of the circuit unit 10B, so that the molding portion 11B itself serves a frame to support and hold the driver 30 in position to function as the independent motor mounting holder of a conventional camera module with a different assembling process than the of conventional COB manufacturing method. In the conventional COB manufacturing method, the independent motor mounting holder of the camera mode is adhered on the circuit board. However, the molding portion 11 of the present invention is provided on the main circuit board 121B by means of molding technique that does not require any adhering and affixing process thereof. The present molding method, with respect to the conventional adhering method, has better connection stability and controllability of process, and that no gluing space is required to be reserved for AA adjustment between the molding portion 11B and the main circuit board 121B that further reduces the adhering space the AA adjustment of the conventional camera module, such that the thickness of camera module can be decreased accordingly. Meanwhile, the electric elements 122B are enclosed, cased and/or wrapped by the molding portion 11B that allows the electric elements and the supporting function can be overlappingly arranged and provided, and has no need to reserve any safety space for the electric elements as required by the conventional camera module. Therefore, a height of the molding portion 11B that can also function as a conventional supporting holder can be provided in a smaller and more compact manner, so as to further provide room to reduce the thickness of camera module. In addition, the replacement of the traditional independent mounting holder with the molding portion 11B of the present invention avoids tilt error caused in the affixing and assembling of conventional mounting holder and reduces accumulated tolerance of the assembling of the camera module.

Further, the molding portion 11B includes a platform 111B which is adapted for installing the optical filter 40 thereon, ensuring the optical filter 40 to be provided above the sensor 50. In other words, light entered the camera lens 20 reaches the sensor 50 after the filtering of the optical filter 40. The optical filter 40 can be embodied as, for example but not limited to, a IR-Cut Filter (IRCF).

The platform 111B of the molding portion 11B has a ring shaped inner groove 110B providing adequate space to install the optical filter 40. It is worth mentioning that the molding portion 11B, which substitutes the traditional mounting holder, connects the driver 30 with the optical filter 40 and provides installation space for the optical filter 40, so that the molding portion 11B, the optical filter 40 and the circuit element 122B are reasonably arranged, that fully uses the remaining space outside the photosensitive area of the sensor 50 so as to minimize the size of the camera module. Also, by means of the molding technique, a flat and smooth platform 111B of the molding portion 11B is provided that enables the optical filter 40 to be evenly and flatly installed to ensure the consistency of light path.

More specifically, the inner groove 110B is a step groove having L-ring shape and communicates with the opening 100B of the molding portion 11B, so that the optical filter 40 can be supported and installed along the photosensitive path of the sensor 50.

It is worth mentioning that in this embodiment of the present invention, the sensor 50 is installed on a lower surface of the main circuit board 121B, wherein the molding portion 11B is molded to surround the external rim of the main circuit board 121B. During the manufacturing of the molded circuit unit 10B, there are various possible manufacturing orders, for example but not limited to that, in one embodiment, the access 12120B can be made in the main circuit board 121B first, while the sensor 50 is invertedly installed at the access 12120B of the main circuit board 121, and then the molding portion 11B is molded to form around the outer sides of the sensor 50 and at the peripheral edges of the main circuit board 121B to enclose, case and/or wrap up the circuit elements 122B protruded from the main circuit board 121B thereon. Besides, in another embodiment of the present invention, the access 12120B can be made in the main circuit board 121B first, and then the peripheral edges of the main circuit board 121B can be molded to form the molding portion 11B to enclose, case and/or wrap up the circuit elements 122B protruded from the main circuit board 121B. Then the sensor 50 is installed on the main circuit board 121B and positioned in the outer groove 12121B of the molding portion 121B. In another alternative mode of the present invention, the peripheral edges of the main circuit board 121B can be first molded to form the molding portion 11B to enclose, case and/or wrap up the circuit elements 122B protruded from the main circuit board 121B. Then the access 12120B is made on the main circuit board 121B and the sensor 50 is invertedly installed at the access 12120B of the main circuit board 121B.

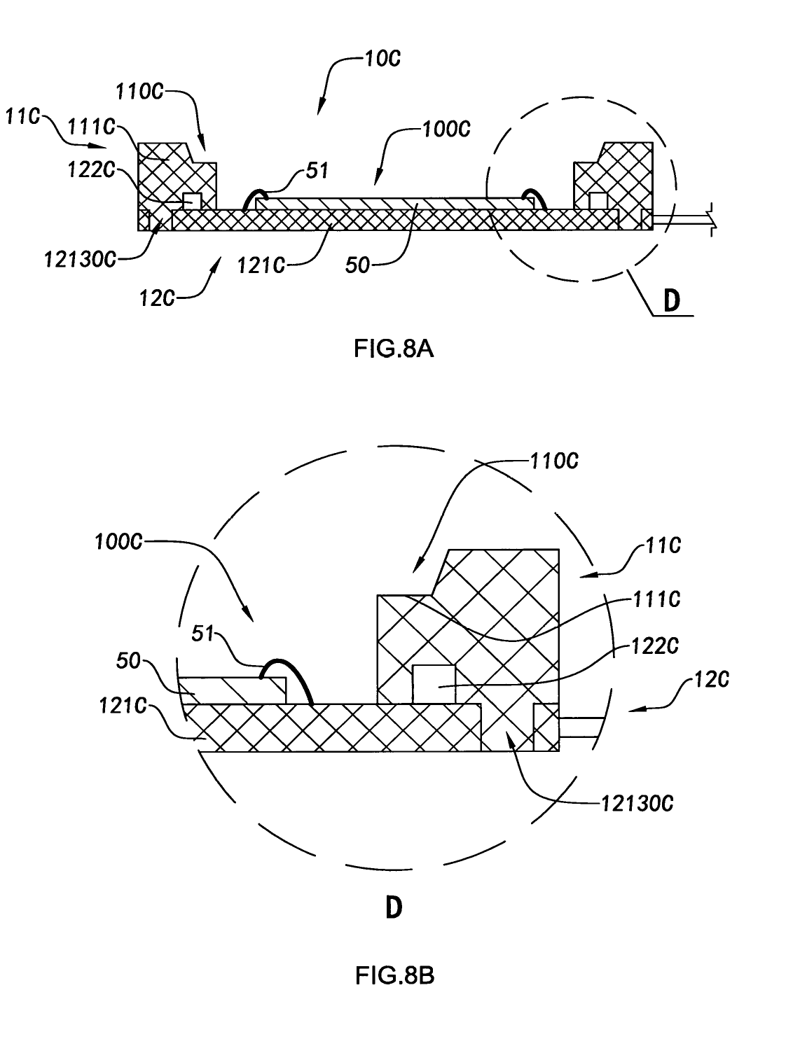

FIGS. 8A and 8B illustrates a molded circuit unit of the camera module according to a third alternative mode of the above first preferred embodiment of the present invention. The molded circuit unit 10C includes a molding portion 11C and a circuit board portion 12C, wherein the molding portion 11C moldingly connects the circuit board portion 12C.

The circuit board portion 12C includes a main circuit board 121C, wherein the sensor 50 is provided on the main circuit board 121C and positioned at the inner side of the molding portion 11C.

Specifically, the driver 30 is installed on the molding portion 11C of the circuit unit 10C and electrically connected with the circuit board portion 12C, wherein the camera lens 20 is installed on the driver 30 which is adapted for autofocusing and the camera lens 20 by the driver 50. The camera lens 20 is positioned along a photosensitive path of the sensor 50, so that when the camera module is capturing image of an object, light reflected from the object can be processed by the camera lens 20 and then received by the sensor 50 for photoelectric conversion.

Further, the circuit board portion 12C includes a photosensitive circuit (not shown in the figures) and at least one circuit element 122C. The photosensitive circuit is preinstalled in the main circuit board 121C, wherein the circuit element 122C is electrically connected with the photosensitive circuit and the sensor 50 to provide for processing of photosensitive function of the sensor 50. The circuit element 122C can be, for example but not limited to, a resistor, a capacitor, a diode, a triode, a potentiometer, or an electric relay.

Particularly, in one embodiment of the present invention, when the camera module is being assembled, the driver 30 is electrically connected to the photosensitive circuit through a conductive wire which is soldered to the main circuit board 121C.

It is worth mentioning that the molding portion 11C encloses, cases and/or wraps up one or more circuit elements 122C therein, so that the circuit element 122C will not be directly exposed in an outer space of the camera module, and more particularly, the circuit elements 122C will not exposed in an enclosed environment that communicates with the sensor 50. This is substantially different from the conventional camera module that its elements are exposed on the circuit board. Accordingly, the circuit elements 122C, such as resistance-capacitance components, is prevented from any dust and sundries staying on the circuit elements 122C and polluting the sensor 50. The molding portion 11C has an opening 100C and the molding portion 11C is molded to surround the outer sides of the sensor 50 that provides a light path between the camera lens 20 and the sensor 50.

Further, the main circuit board 121C has one or more holding holes 12130C provided therein, wherein the molding portion 11C fills and inserts into the holding holes 12130C. Each of the holding holes 12130C is provided in a molding area of the main circuit board and arranged coordinately with the circuit elements 122C. It is worth mentioning that the presence of the holding holes 12130C allow the molding portion 11C to fill and insert into the main circuit board 121C when it is molded to form on the main circuit board 121C, which enhances the bonding ability between the molding portion 11C and the main circuit board 121C, so that the molding portion 11C will not detach from the main circuit board easily while the structural strength of the main circuit board 121C is also increased, so that the main circuit board 121C is adapted to have a thinner thickness.

The positions and quantity of the holding holes 12130 can be arranged based on the substantial needs. Therefore, those skilled in the art should understand that the position and quantity of the holding hole 12130 should not be a limitation of the present invention.

It is worth mentioning that in other alternative modes of the present invention, the main circuit board 121C can also provide the inner groove 12110A or the access 12120B to allow the molded circuit unit 10C to have various advantages, including thinner thickness and higher structural strength.

It is worth mentioning that presence of the holding holes 12130C on the circuit board 121C of this preferred embodiment can provide benefits, including enhancing the molding bonding ability between the main circuit board 121C and the molding portion 11C and increasing the structural strength of the main circuit board 121C. Those skilled in the art should certainly understand that the presence of the holding holes 12130C in the circuit board 121C should not be a limitation of the present invention. In other words, other embodiments of the present invention may not contain the holding hole 12130C or provide the holding hole 12130C in different arrangement or different quantity based on the requirement.

Specifically, during the manufacturing of the molded circuit unit, a conventional circuit board can be used as the main circuit board 121C and the molding is conducted on the surface of the main circuit board 121C. For example, a circuit board that has been treated with Surface Mount Technology (SMT), can be molded to form the molding portion 11C by insert molding technique with an injection molding machine, or to form the molding portion 11C by pressing molding technique that is commonly used in semiconductor packaging. The main circuit board 121C can alternatively be, for example but not limited to, a rigid-flex board, a ceramic substrate (without flexible board), a rigid PCB (without flexible board), and etc. The way to form the molding portion 11C can be, for example but not limited to, injection molding, insert molding, die molding or pressing molding. The material of the molding portion 11C can be, for example but not limited to, nylon, LCP (Liquid Crystal Polymer), or PP (Polypropylene) for injection molding or insert molding, and resin for die molding or pressing molding. Those skilled in the art should understand that the above recited manufacturing methods and optional materials are just to give examples to illustrate implementations of the present invention, rather than to limit of the present invention.

It is also worth mentioning that the driver 30 is installed on the molding portion 11C of the circuit unit 10C, so that the molding portion 11C itself also serves a frame to support and hold the driver 30 in position to function as the independent mounting holder of a conventional camera module with a different assembling process than the conventional COB technique. In the conventional COB technique, the independent motor mounting holder of the camera module is adhered on the circuit board. However, the molding portion 11C of the present invention is provided on the main circuit board 121C by means of molding technique that does not require any adhering and affixing process therefor. The present molding method, with respect to the conventional adhering method, has better connection stability and controllability of process and that no gluing space is required to be reserved for AA adjustment between the molding portion 11C and the main circuit board 121C, that further reduces the adhering space for the AA adjustment of the conventional camera module, such that the thickness of camera module can be decreased accordingly. Meanwhile, the electric elements 122C are enclosed, cased and/or wrapped by the molding portion 11C that allows the electric elements 122C and the supporting function being overlappedly arranged and provided, and has no need to reserve any safety space for the electric elements as required by the conventional camera module. Therefore, the height of the molding portion 11C that also functions as a supporting frame can be provided in a smaller and more compact manner, so as to further provide room to reduce the thickness of camera module. Besides, the replacement of traditional independent mounting holder with the molding portion 11C of the present invention avoids tilt error caused in the affixing and assembling of conventional mounting holder and reduces accumulated tolerance of the assembling of the camera module.

Further, the molding portion 11C includes a platform 111C which is adapted for installing the optical filter 40 thereon, that ensures the optical filter 40 to be provided above the sensor 50. In other words, light entered the camera lens 20 reaches the sensor 50 after the filtering of the optical filter 40. The optical filter 40 can be embodied as, for example but not limited to, a IR-Cut Filter (IRCF).

The platform 111C of the molding portion 11C has a ring shaped inner groove 110C provided therein so as to provide adequate space to install the optical filter 40. It is worth mentioning that the molding portion 11C, which substitutes the traditional motor mounting holder, connects the driver 30 with the optical filter 40 and provides installation space for the optical filter 40, so that the molding portion 11C, the optical filter 40 and the circuit element 122C are reasonably arranged, that fully employs the remaining space outside of the photosensitive area of the sensor 50 to minimize the size of the camera module. Also, by means of the molding technique, a flat and smooth platform 111C of the molding portion 11C is provided that enables the optical filter 40 to be evenly and flatly installed to ensure the consistency of light path.

More specifically, the inner ring groove 110C is a step groove having a L-ring shape and communicates with an opening 100C of the molding portion 11C, so that the optical filter 40 can be supported along the photosensitive path of the sensor 50.

According to this embodiment of the present invention, the sensor 50 is electrically connected with the main circuit board 121C through a series of lead wires 51, and electrically connected with the photosensitive circuit. The lead wires 51 can be embodied as, for example but not limited to, gold wires, copper wires, aluminum wires, or silver wires. Particularly, the lead wires 51 of the sensor 50 can be connected with the main circuit board 121C through conventional COB method, for example but not limited to, welding and soldering. It is worth mentioning that the lead wires 51 are also electric element protruded on the main circuit board 121C according to the present invention that can be enclosed, cased and/or wrapped up by the molding portion 11C. In other words, the connection between the sensor 50 and the main circuit board 121C can use current connection means to reduce the improvement cost of technology, to fully apply the conventional art and equipments, and to avoid the waste of resources. Without doubt, those skilled in the art should be able to understand that the connection between the sensor 50 and the main circuit board 121C may also be embodied as any other way of connection that is able to achieve the object of the present invention, wherein the present invention is not confined in this regard.

It is worth mentioning that in this embodiment of the present invention, the sensor 50 is provided on the upper surface of the main circuit board 121C, wherein the molding portion 11C is positioned to surround the outer side of the sensor. During the manufacturing of the molded circuit unit, there are various possible manufacturing orders, for example but not limited to that, in one embodiment, the sensor 50 can be installed on the main circuit board 121C first, and then the molding portion 11C is formed around the outer sides of the sensor 50 and at the peripheral edges of the main circuit board 121C to enclose, case and/or wrap up the circuit elements 122C protruded from the main circuit board 121C therein. Besides, in an alternative mode of the present invention, the peripheral edges of the main circuit board 121C can be molded to form the molding portion 11C first to enclose, case and/or wrap up the circuit elements 122C protruded from the main circuit board 121C therein. Then the sensor 50 can be installed on the main circuit board 121C and positioned within the inner sides of the molding portion 11C.

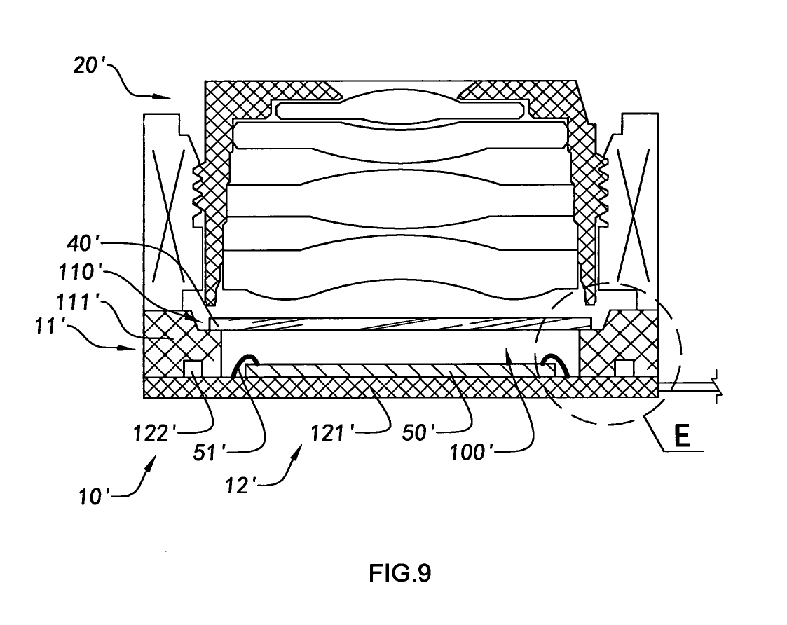

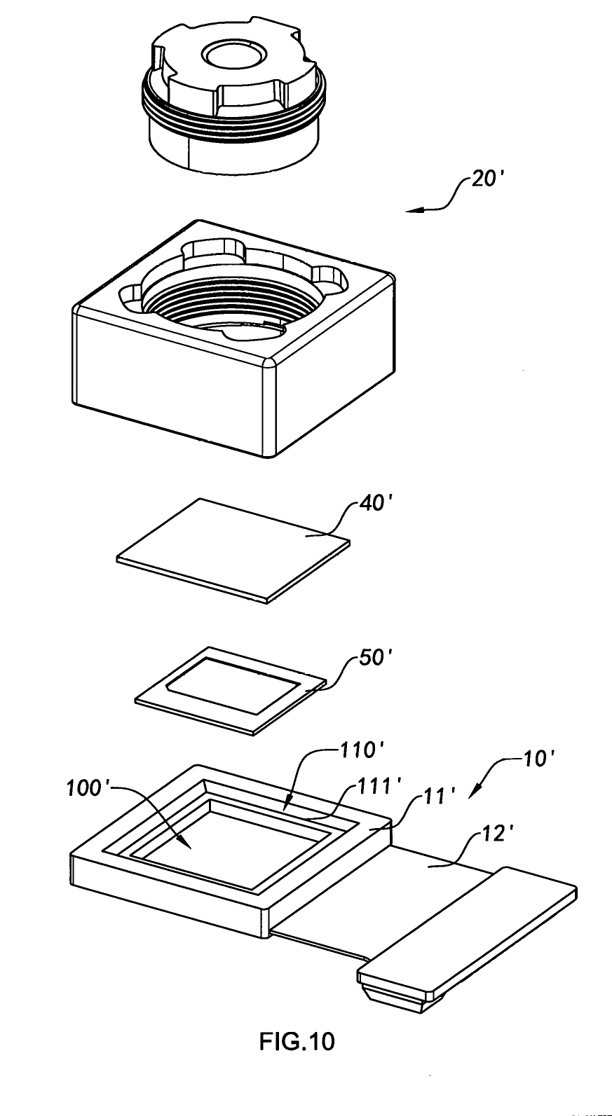

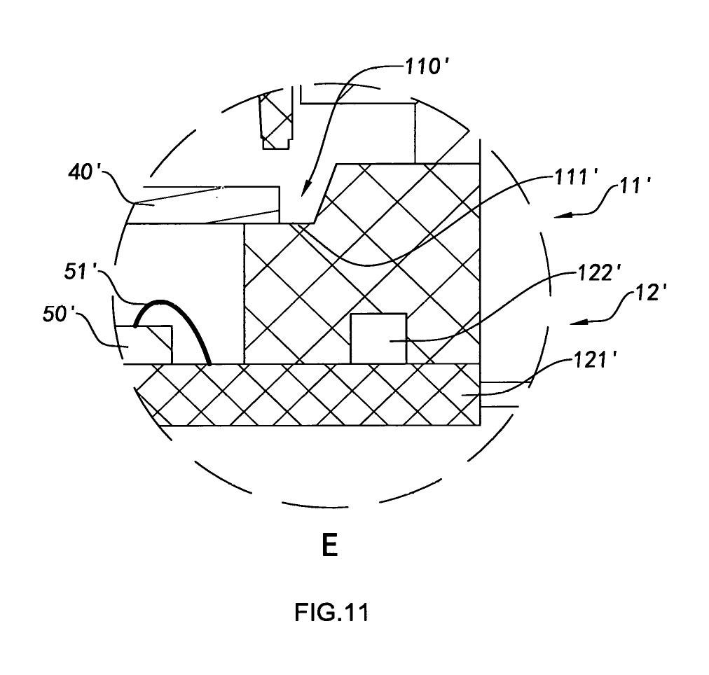

FIGS. 9-11 illustrate is a camera module according to a second preferred embodiment of the present invention. The camera module is embodied as a fixed focus camera module. The camera module includes a molded circuit unit 10′, a camera lens 20′ and a sensor 50′ such as a photosensitive chip.

The camera lens 20′ is installed above the molded circuit unit 10′. The molded circuit unit 10′ includes a molding portion 11′ and a circuit board portion 12′, wherein the molding portion 11′ is molded to connect with the circuit board portion 12′.

The circuit board portion 12′ includes a main circuit board 121′, wherein the sensor 50′ is installed on the main circuit board 121′ within the space defined by the inner sides of the molding portion 11′.

Specifically, the camera lens 20′ is positioned along a photosensitive path of the sensor 50′, so that when the camera module is capturing image of an object, light reflected from the object is processed by the camera lens 20′ first and then received by the sensor 50′ which is adapted for photoelectric conversion.

Further, the circuit board portion 12′ includes a built-in photosensitive circuit (not shown in the figures) and at least one circuit element 122. The photosensitive circuit is preinstalled in the main circuit board 121′, wherein the circuit element 122′ is electrically connected with the photosensitive circuit and the sensor 50′ to provide for processing photosensitive operation of the sensor 50′. The circuit element 122′ can be, for example but not limited to, a resistor, a capacitor, a diode, a triode, a potentiometer, or an electric relay.

It is worth mentioning that the molding portion 11′ is molded to enclose, case and/or wrap up the circuit element 122′ therein, so that the circuit elements 122′ will not be directly exposed in an outer space, and more particularly, the circuit elements 122′ will not be exposed in an enclosed environment that communicates with the sensor 50′. This is substantially different from the conventional camera module that its circuit elements are exposed on the circuit board. Accordingly, the circuit elements 122′, such as resistance-capacitance components, are prevented from any dust and sundries staying on the circuit element 122′ and polluting the sensor 50′ of the second preferred embodiment. The molding portion 11′ has an opening 100′ provided therein, rendering the molding portion 11′ to be positioned surrounding the outer sides of the sensor 50′ and providing a light path between the camera lens 20′ and the sensor 50′.

Specifically, during the manufacturing of the molded circuit unit 11′, a conventional circuit board can be used as the main circuit board 121′ and the molding portion 11′ is molded on the surface of the main circuit board 121′. For example, a circuit board that has been treated with Surface Mount Technology (SMT) can be molded to form the molding portion 11′ by insert molding technique with an injection molding machine, or to form the molding portion 11 by pressing molding technique that is commonly used in semiconductor packaging. The main circuit board 121′ can alternatively be, for example but not limited to, a rigid-flex board, a ceramic substrate (without flexible board), a rigid PCB (without flexible board), and etc. The molding portion 11′ can possibly be moldingly formed by, for example but not limited to, injection molding, insert molding, die molding, or pressing molding. The material of the molding portion 11′ can be, for example but not limited to, nylon, LCP (Liquid Crystal Polymer), or PP (Polypropylene) for injection molding and insert molding, and resin for die molding and pressing molding. Those skilled in the art should understand that the above possible manufacturing methods and optional materials are just to give examples to illustrate embodiments of the present invention, rather than to limit of the present invention.

It is also worth mentioning that the camera lens 20′ is installed on the molding portion 11′ of the circuit unit 10′, so that the molding portion 11′ itself also serves a supporting frame functioning as of an independent motor mounting holder of a conventional camera module to support and hold the camera lens 20′ in position, but with a different assembling process than the conventional COB technique. According to the conventional COB technique, the independent motor mounting holder is adhered on circuit board. However, the molding portion 11′ of the present invention is connected with the main circuit board 121′ with molding technique that does not require any adhering and affixing process. The molding method of the present invention has better connection stability and controllability of process than the conventional adhering and affixing method. Also, the gluing space reserved for AA adjustment between the molding portion 11′ and the main circuit board 121′ is not required. In other words, the adhering space for AA adjustment of the conventional camera module is reduced, such that the thickness of camera module can thus be further decreased. Meanwhile, the molding portion 11′ is molded to enclose, case and/or wrap up the circuit element 122′ that allows the molding portion 11′ not only enclosing the electric elements 122′ therein but also functioning as supporting the driver 30′ as the traditional functions of holder so that the molding portion 11′ and the circuit elements 122′ are overlappingly arranged, rather than reserving the safety distance around the circuit components, like conventional camera module. Therefore, the height of the molding portion 11′ that also provides the frame supporting functions can be arranged in a smaller and smoother manner, so as to further provide room to reduce the thickness of camera module to obtain a fixed focus camera module with thinner thickness. Besides, the replacement of the independent motor mounting holder of the conventional camera module with the molding portion 11′ of the present invention substantially avoids tilt error caused in the affixing and assembling of conventional independent motor mounting holder and reduces accumulated tolerance of the assembling of the camera module.

Further, the molding portion 11′ includes a platform 111′ which is adaptable for installing an optical filter 40′ such as IR filter thereon, so that the optical filter 40′ is positioned above the sensor 50′. In other words, light entered the camera lens 20′ reaches the sensor 50′ after it was processed by the optical filter 40′. The optical filter 40′ can be embodied as, for example but not limited to, a IR-Cut Filter (IRCF).

The platform 111′ of the molding portion 11′ has a ring shape inner groove 110′ to provide adequate installation space for the optical filter 40′. It is worth mentioning that the molding portion 11′ that substitutes the traditional mounting holder, is arranged to connect with the camera lens 20′ to the circuit board portion 12′ and to provide installation space for the optical filter 40′, so as to arrange the molding portion 11′, the optical filter 40′ and the circuit element 122′ to fully employ the remaining space outside of the photosensitive area of the sensor 50′ to minimize the thickness of the camera module. Therefor, the molding technique applied in the present invention allows the molding portion 11′ to provide the platform 111′ in a flat and smooth manner, so that the optical filter 40′ can be evenly and flatly installed to ensure the consistency of light path.

More specifically, the inner groove 110′ is a step groove having a L-ring shape and communicates with an opening 100′ of the molding portion 11′, so that the optical filter 40′ can be supported and installed along the photosensitive path of the sensor 50′.

According to this second preferred embodiment of the present invention, the sensor 50′ is electrically connected to the main circuit board 121′ through a series of lead wires 51′, and electrically connected to the photosensitive circuit. The lead wires 51′ can be embodied as, for example but not limited to, gold wires, copper wires, aluminum wires, or silver wires. Particularly, the sensor 50′ and the series of lead wires 51′ can electrically connect to the main circuit board 121′ by conventional COB method, for example but not limited to, welding or soldering. It is worth mentioning that the lead wires 51′ are electric elements as embodied in the present invention, adapted to be enclosed, cased and/or wrapped up by the molding portion 11′ too. In other words, the connection between the sensor 50′ and the main circuit board 121′ may use current connection means to reduce the improvement cost of technology, to full apply the conventional art and equipments, and to avoid the waste of resources. Without doubt, those skilled in the art should be able to understand that the connection between the sensor 50′ and the main circuit board 121′ may also be embodied as any other way of connection that is able to achieve the object of the present invention, wherein the present invention is not confined in this regard.

It is worth mentioning that in a conventional manufacturing process, circuit board has the resistance-capacitance components attached thereon through SMT first. Then, by means of the conventional COB packaging process, the circuit board attaches the chip thereon, connects the gold wires, and finally adhering the plastic motor mounting holder or motor thereon with glue. However, according to the manufacturing method of the present invention, after the SMT, the molding portion 11 is molded to form on the surface of the circuit board through molding technique, and then the process of chip attachment and gold wire connection is processed.

It is worth mentioning that in this embodiment of the present invention, the sensor 50′ is provided on the upper surface of the main circuit board 121′, wherein the molding portion 11′ is molded to surround the outer sides of the sensor 50′. During the manufacturing of the molded circuit unit, there are various possible manufacturing orders, for example but not limited to that, in one embodiment, the sensor 50′ can be installed on the main circuit board 121′ first, and then the molding portion 11′ is molded to form around the outer sides of the sensor 50′ and at the peripheral edges of the main circuit board 121′ to enclose, case and/or wrap up the circuit elements 122′ protruded from the main circuit board 121′ therein. Besides in an alternative mode of the second preferred embodiment of the present invention, the peripheral edges of the main circuit board 121′ can be first molded to form the molding portion 11′ and to enclose, case and/or wrap up the circuit elements 122′ protruded from the main circuit board 121′ therein. Then the sensor 50′ can be installed on the main circuit board 121′ and positioned within the space defined by the inner sides of the molding portion 11′.

It is worth mentioning that the camera lens 20′ can also be assembled to form the molded circuit unit with various alternative modes of the above preferred embodiments, that can make the fixed focus camera module with different structures. That is to say, the camera lens 20′ can respectively be assembled to the molded circuit unit 10A, the molded circuit unit 10B, and the molded circuit unit 10C, to compose various fixed focus camera modules. Structures of the molded circuit units are referred to the above preferred embodiments, but herein described again.

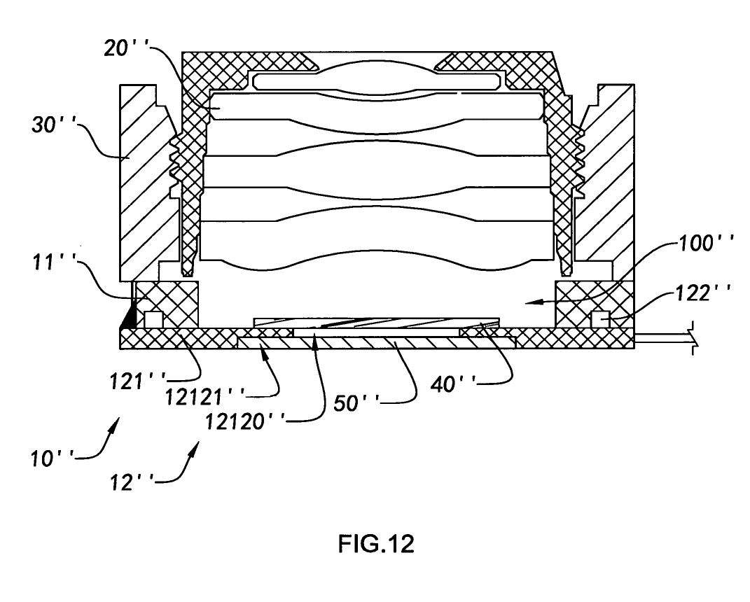

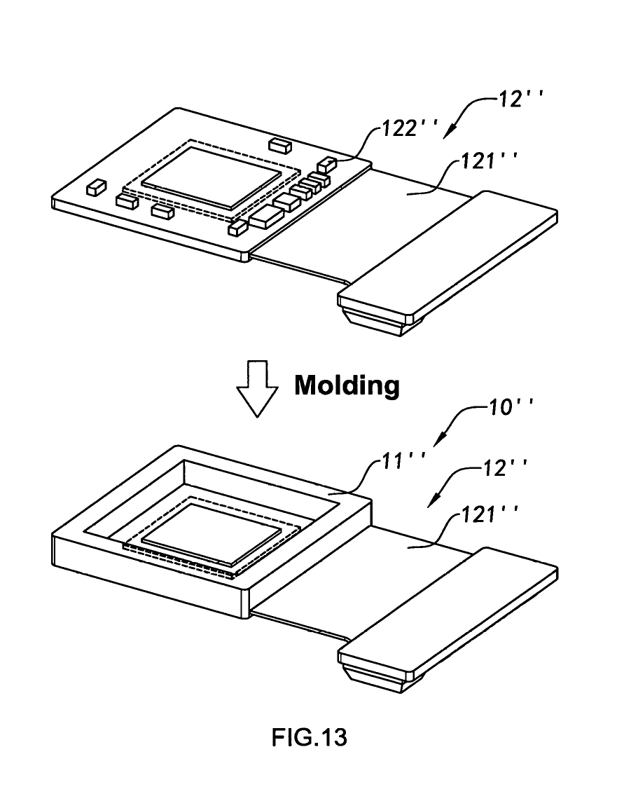

FIGS. 12 and 13 illustrate is a camera module according to a third preferred embodiment of the present invention. The camera module is a zoom lens camera module, which includes a molded circuit unit 10″, a camera lens 20″ and a driver 30″ such as a motor.

The driver 30″ is installed on the molded circuit unit 10″, wherein the camera lens 20″ is installed on the driver 30″, so as to have the camera lens 20″ be supported above the molded circuit unit 10″.

The molded circuit unit 10″ includes a molding portion 11″ and a circuit board portion 12″, wherein the molding portion 11″ moldingly connects the circuit board portion 12″.

The circuit board portion 12″ includes a main circuit board 121″ and a sensor 50″, such as a photosensitive chip, wherein the sensor 50″ is installed on the main circuit board 121″ and positioned within a space defined by the inner sides of the molding portion 11″.

Specifically, the driver 30″ is installed on the molding portion 11″ of the molded circuit unit 10″ and electrically connected with the circuit board portion 12″, wherein the camera lens 20″ is installed on the driver 30″ which is adapted for autofocusing the camera lens 20″ by the driver 30″. The camera lens 20″ is positioned along a photosensitive path of the sensor 50″, so that when the camera module is capturing image of an object, light reflected from the object can be processed by the camera lens 20″ and then received by the sensor 50″ for photoelectric conversion.

Further, the circuit board portion 12″ includes a built-in photosensitive circuit (not shown in the figures) and at least one circuit element 122″. The photosensitive circuit is preinstalled in the main circuit board 121″, wherein the circuit element 122″ is electrically connected with the photosensitive circuit and the sensor 50″ to provide for processing of photosensitive work of the sensor 50″. The circuit element 122″ can be, for example but not limited to, a resistor, a capacitor, a diode, a triode, a potentiometer, or an electric relay.

Particularly, in one embodiment of the present invention, when the camera module is being assembled, the driver 30″ is electrically connected to the photosensitive circuit through a conductive wire, and the conductive wire is soldered on the main circuit board 121″.

It is worth mentioning that the molding portion 11″ is arranged to enclose, case and/or wrap up one or more circuit elements 122″ therein, so that the circuit element 122″ will not be directly exposed in the outer space, and more particularly, the circuit elements 122″ will not be exposed in an enclosed environment that communicates with the sensor 50″. This is substantially different from the conventional camera module that its circuit elements are exposed on the circuit board. Accordingly, the circuit elements 122″, such as resistance-capacitance components, are prevented from any dust and sundries staying on the circuit element and polluting the sensor 50″ according to the present invention. The molding portion 11″ has an opening 100″ rendering the molding portion 11″ being positioned to surround the outer sides of the sensor 50″ and providing a light path between the camera lens 20″ and the sensor 50″.

Further, the main circuit board 121″ has an access 12120″ provided therein, wherein a lower part of the access 12120″ is adapted for installation of the sensor 50″. The access 12120″ communicates the upper and lower sides of the main circuit hoard 121″, so that when the sensor 50″ is installed on the main circuit board 121″ from the back of the main circuit board 121″ with the photosensitive area facing up, the photosensitive area of the sensor 50″ is adapted to receive incoming light from the camera lens 20″.

Further, the access 12120″ has a ring shaped outer groove 12121″ to provide an installation site for the sensor 50″. Particularly, as the sensor 50″ being installed in the outer groove 12121″, the outer surface of the sensor 50″ is preferred to be aligned flatly with the surface of the main circuit board 121″ in the same plane, so as to ensure the evenness and smoothness of the surface of the molded circuit unit 10″.

According to this embodiment of the present invention, the access 12120″ has a step shape that facilitates the installation of the sensor 50″ easily and provides a stable installation site for the sensor 50″, ensuring the photosensitive area of the sensor 50″ positioned in the inner space of the access 12120″.

It is worth mentioning that this embodiment of the present invention provides a way of chip installation that is different from conventional way, that is the flip chip method. The sensor 50″ of the present invention is installed on the main circuit board 121″ from the reverse direction of the main circuit board 121″, which is different from the above embodiment that requires installation on the main circuit board 121 from the front side of the main circuit board 121, i.e. from the upper side of the main circuit board 121 with the photosensitive area of the sensor 50 facing upwardly. This structure and installation method allow the sensor 50″ and the molding portion 11″ to be relatively independent. Installation of the sensor 50″ will not be affected by the molding portion 11″. Molding of the molding portion 11″ also makes less impact to the sensor 50″. Besides, the sensor 50″ is embedded in the outer side of the main circuit board 121″ without protruding to the inner side of the main circuit board 121″, in order to leave a larger space in the inner side of the main circuit board 121″, so that the height of the molding portion 11″ will not be limited by the height of the sensor 50″, which allows the molding portion 11″ to achieve a smaller height.

Specifically, during the manufacturing of the molded circuit unit, a conventional circuit board would be used as the main circuit board 121″ and the molding is conducted on the surface of the main circuit board 121″. For example, a circuit board, that has been treated with Surface Mount Technology (SMT), can be molded to form the molding portion 11″ by insert molding technique with an injection molding machine, or to form the molding portion 11″ by pressing molding technique that is commonly used in semiconductor packaging. Also, the access 12120″ is made in the main circuit board 121″. The main circuit board 121″ can alternatively be, for example but not limited to, a rigid-flex board, a ceramic substrate (without flexible board), a rigid PCB (without flexible board), and etc. The molding portion 11″ can possibly be made by, for example but not limited to, injection moulding, insert molding, die molding, pressing molding, or etc. The material of the molding portion 11″ can be, for example but not limited to, nylon, LCP (Liquid Crystal Polymer), or PP (Polypropylene) for injection molding and insert molding, and resin for die molding and pressing molding. Those skilled in the art should understand that the above possible manufacturing methods and optional materials are just to give examples to illustrate implementations of the present invention, rather than to limit the present invention.

It is also worth mentioning that the driver 30″ is installed on the molding portion 11″ of the circuit unit 10″, so that the molding portion 11″ itself also serves to support and hold the motto 30″ in position that functions as a supporting frame like the independent motor mounting holder of the conventional camera module with a different assembling process. In the conventional COB manufacturing method, the independent motor mounting holder is adhered on the circuit board. However, the molding portion 11″ of the present invention is provided on the main circuit board 121″ by means of molding technique that does not require any adhering and affixing process therefor. The present molding method, with respect to the conventional adhering method, has better connection stability and controllability of process, and that no gliding space is required to be reserved for AA adjustment between the molding portion 11″ and the main circuit board 121″, that further reduces the adhering space for the AA adjustment of the conventional camera module, such that the thickness of camera module can be decreased accordingly. Meanwhile, the electric elements 122″ are enclosed, cased and/or wrapped by the molding portion 11″ that allows the electric elements and the motor mounting holder of the conventional camera module can be overlappingly arranged and provided in the present invention without the need of reserving any safety space for the electric elements as required by the conventional camera module. Therefore, a height of the molding portion 11″ that can also function as a supporting frame can be provided in a smaller an more compact manner, so as to further provide room to reduce the thickness of camera module. In addition, the replacement of the traditional independent mounting holder with the molding portion 11″ of the present invention substantially avoids tilt error caused in the affixing and assembling of the conventional independent motor mounting holder and reduces accumulated tolerance of the assembling of the camera module.

It is worth mentioning that, according to an alternative mode of the preferred embodiment, the camera module includes an optical filter 40″ such as IR filter which is installed on the main circuit board 121″ and positioned above the sensor 50″, that is positioned at an upper opening of the access 12120″ of the main circuit board 121″, so that light that entered from the camera lens 20″ will be processed by the optical filter 40″ while passing through the access 12120″. Also, alternatively, the molding portion 11″ does not require to provide installation site for the optical filter 40″ nor the platform 111 as taught in the above embodiments. Rather, the main circuit board 11″ provides an installation site for the optical filter 40″, which reduces a distance between the optical filter 40″ and the sensor 50″, so that the height of the molding portion 11″ can further be decreased.

The optical filter 40″ can be embodied as, for example but not limited to, a IR-Cut Filter (IRCF).

It is worth mentioning that according to the present invention, by means of the application of FC (Flip Chip) setting in the access 12120″, the optical filter 40″ can be installed on the main circuit board 121″, so as to enable the molded circuit unit 10″ and the camera module assembled with the molded circuit unit 10″ to contain the advantages based on the FC installation method and the above mentioned installation method of the optical filter 40″, including convenience in assembling and reduction of thickness. However, those skilled in the art should understand that the installation position of the optical filter 40″ should not be construed as limitation of the present invention, wherein, in other embodiment of the present invention, the optical filter 40″ can also be installed at different positions, for example but not limited to, such as the molding portion 11, frame, and driver.

It is worth mentioning that the molding portion 11″ substitutes the traditional independent motor mounting holder to connect the driver 30″ with the circuit board portion 12″ and to provide installation site for the optical filter 40″, so as to reasonably arrange the molding portion 11″, the optical filter 40″ and the circuit element 122″ to fully utilize the free space outside of the photosensitive area of the sensor 50″ to minimize the size of the camera module. In addition, the benefit of utilizing the molding technique in the present invention allows the molding portion 11″ to not only provide a flat and smooth position for the driver 30″ to be evenly and flatly installed, but also ensure the consistency of light path.

It is worth mentioning that in this embodiment of the present invention, the sensor 50″ is installed on the lower surface of the main circuit board 121″, wherein the molding portion 11″ is molded to surround the outer peripheral edges of the main circuit board 121″. During the manufacturing of the molded circuit unit 10″, there are various possible manufacturing orders, for example but not limited to that, in one embodiment, the access 12120″ can be formed in the main circuit board 121″, and then the sensor 50″ is invertedly installed at the access 12120″ of the main circuit board 121″, and then the molding portion 11″ is molded to form around the outer sides of the sensor 50″ and positioned at the peripheral edges of the main circuit board 121″ to enclose, case and/or wrap up the circuit elements 122″ protruded from the main circuit board 121″ therein. Besides, in another embodiment of the present invention, the access 12120″ can be made in the main circuit board 121″ first, and then the peripheral edges of the main circuit board 121″ can be molded to form the molding portion 121″ to enclose, case and/or wrap up the circuit elements 122″ protruded from the main circuit board 121″ therein. Then the sensor 50″ is installed on the main circuit board 121″ and positioned within the outer groove 12121″ of the molding portion 11″. In another embodiment of the present invention, the peripheral edges of the main circuit board 121″ can be molded to form the molding portion 11″ to enclose, case and/or wrap up the circuit elements 122″ protruded from the main circuit board 121″ therein first. Then the access 12120″ is made in the main circuit board 121″, so the sensor 50″ can be invertedly installed at the access 12120″ of the main circuit board 121″.

It is worth mentioning that the installation process of the molded circuit unit 10″ and the optical filter 40″ can also be applied to fixed focus camera module.

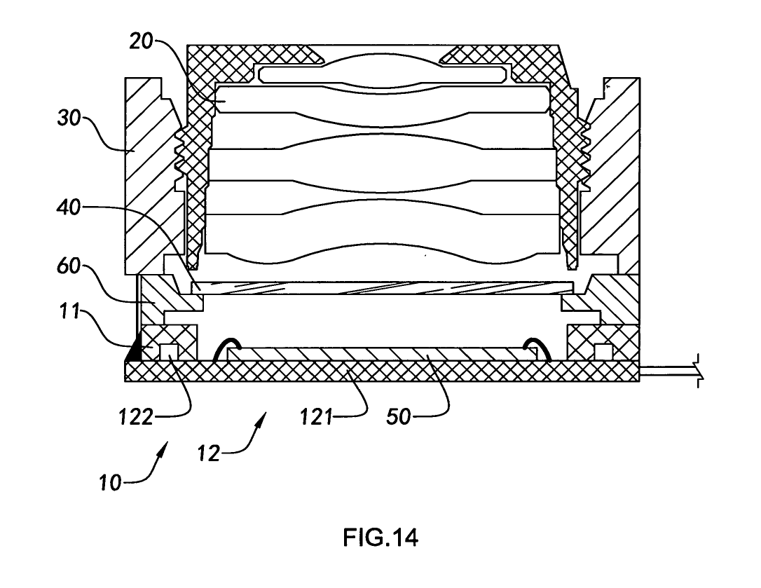

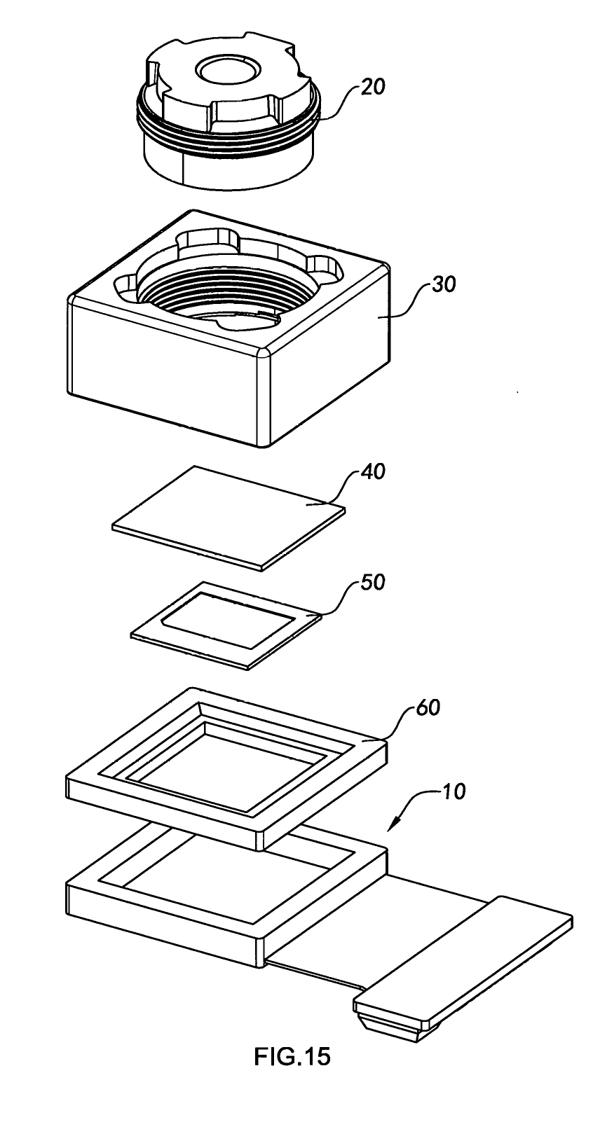

FIGS. 14 and 15 illustrate a camera module according to a fourth preferred embodiment of the present invention, which is different from the above first preferred embodiment that the camera module also includes a supporting frame 60. The frame 60 is installed on the molded circuit unit 10, wherein the driver 30 is installed on the supporting frame 60 and the camera lens 20 is installed to the driver 30, so that the camera lens 20 is supported and held above the molded circuit unit 10. In other words, it is an apparent alternative that the molded circuit units 10, 10A, 10B, 10C can also be assembled with a conventional supporting holder to produce different types of camera module, such as zoom lens camera module and fixed focus camera module. Accordingly, the optical filter 40 can optionally be installed on the supporting frame 60, the molding portion 11, or the driver 30.

In view of the above preferred embodiments and alternative modes thereof that the application of the molding technique to the camera module increases the competitiveness of such product in the market, particularly in high-end products. The camera module of the present invention mainly provides the following advantages:

1. Being able to reduce the length and width size of the camera module. The molding part and the electric elements, including the resistance-capacitance parts, can be overlapped spatially.

The independent mounting holder of the conventional camera module requires the reserve of a safety distance therefor, while the molding manufacturing method of the present invention can directly utilize the space around the capacitors to directly fill with plastic material to form the molding portion enclosing the capacitors and serving as a frame at the same time.

2. Reducing module tilt. The molding part can substitute the current plastic holder design to decrease the accumulated tolerance.

3. The molding of the circuit board enhances the structural strength of the circuit board. Under the same structural strength, the molding portion can play a supporting ability, increase the strength, further reduce the thickness of the circuit board, and reduce the height of the camera module.

4. In view of height space, assembling safety space must be reserved for the conventional camera module, but it does not require to reserve such space with the application of the molding technique while reducing the height of the camera module according to the present invention.

Conventional camera module needs to reserve a safety gap between the top of the capacitors and the mounting holder to prevent interference. However, the present invention allows plastic material directly filling around the circuit elements, such as capacitors, that the plastic material acts as an insulation for interference and does not require reserving space and gap.

5. Electric elements such as resistors and capacitors can be molded to be enclosed, cased and/or wrapped up, that avoids the area of these resistance-capacitance component be affected and damaged by solder resist, dust, and so on so as to increase product yield rate.

6. Being suitable for high efficient and large scale mass production.

Those skilled in the art shall understand that the above mentioned embodiments of the present invention in the descriptions and figures are to give examples, but to confine the present invention. Objectives of the present invention are completely and effectively implemented. Notions of the functions and structures of the present invention have been shown and described in the embodiments, whereas implementations of the present invention may have modifications or changes in any ways without going against the above notions.

One skilled in the art will understand that the embodiment of the present invention as shown in the drawings and described above is exemplary only and not intended to be limiting.

It will thus be seen that the objects of the present invention have been fully and effectively accomplished. The embodiments have been shown and described for the purposes of illustrating the functional and structural principles of the present invention and is subject to change without departure from such principles. Therefore, this invention includes all modifications encompassed within the spirit and scope of the following claims.

1. A camera module, comprising:
a camera lens;
a photosensitive sensor; and
a molded circuit unit, which comprises a circuit board portion and a molding portion molded to form on said circuit board portion, wherein said camera lens is supported to be positioned along a photosensitive path of said sensor, wherein said sensor is electrically connected with said circuit unit.

2. The camera module, as recited in claim 1, wherein said circuit board portion comprises a main circuit board and at least a circuit element provided and protruded on the surface of said main circuit board, and said molding portion is molded to integrally connect with said main circuit board.

3. The camera module, as recited in claim 1, wherein said circuit board portion comprises a main circuit board and at least a circuit element provided and protruded on the surface of said main circuit board, wherein said molding portion encloses said circuit element.

4. The camera module, as recited in claim 3, wherein said sensor is installed on the top surface of said main circuit board and said molding portion is positioned at the outer side of said sensor.

5. The camera module, as recited in claim 3, wherein said main circuit board has an inner groove, wherein said sensor is configured to be installed in said inner groove.

6. The camera module, as recited in claim 3, wherein said main circuit board has an access provided therein and is configured to allow said sensor be installed in said access from the back of said main circuit board.

7. The camera module, as recited in claim 6, wherein said access has a step shape cross section.

8. The camera module, as recited in claim 2, wherein said main circuit board has one or more holding holes provided therein, wherein said molding portion extends and fills in said holding hole to enhance a connection strength between said molding portion and said main circuit board.

9. The camera module, as recited in claim 3, wherein said main circuit board has one or more holding holes provided therein, wherein said molding portion extends and fills in said holding hole to enhance a connection strength between said molding portion and said main circuit board.

10. The camera module, as recited in claim 4, wherein said main circuit board has one or more holding holes provided therein, wherein said molding portion extends and fills in said holding hole to enhance a connection strength between said molding portion and said main circuit board.

11. The camera module, as recited in claim 2, wherein said molding portion is protrudingly molded to surround the outer sides of said sensor.

12. The camera module, as recited in claim 1, further comprising an optical filter being supported at said molding portion.

13. The camera module, as recited in claim 12, wherein said molding portion has a platform that forms a ring shape inner groove and is configured to support and connect said optical filter of said camera module.

14. The camera module, as recited in claim 1, further comprising a frame which is installed on said molded circuit unit, wherein said camera lens is installed on said frame.

15. The camera module, as recited in claim 14, further comprising an optical filter being supported at said frame.

16. The camera module, as recited in claim 1, further comprising a driver installed on said molding portion of said molded circuit unit and said camera lens is coupled with said driver.

17. The camera module, as recited in claim 3, wherein a material of said main circuit board is selected from the group consisting of rigid-flex board, ceramic substrate, and rigid PCB.

18. The camera module, as recited in claim 3, wherein a material of said molding portion is selected from the group consisting of nylon, LCP, PP, and resin.

19. The camera module, as recited in claim 1, wherein said molding portion is made by a molding technique selected from the group concession of injection molding, insert molding, die molding, and pressing molding.

20. The camera module, as recited in claim 3, wherein said molding portion is made by a molding technique selected from the group concession of injection molding, insert molding, die molding, and pressing molding.

21. A method of manufacturing a molded circuit unit for electrically connecting a photosensitive sensor and supporting a camera lens at a positioned along a photosensitive path of said sensor thereon, comprising the steps of:
(a) providing a circuit board which comprises a main circuit board and at least a circuit element protruded on the surface of said main circuit board; and
(b) molding a molding portion on said circuit board to enclose said circuit element therein and to integrally connect with said main circuit board.

22. The method, as recited in claim 21, wherein said sensor is installed on the top surface of said main circuit board before the molding step (b) and said molding portion is molded to position at the outer side of said sensor.

23. The method, as recited in claim 21, wherein said sensor is installed on the top surface of said main circuit board after the molding step (b) while said molding portion is positioned at the outer side of said sensor.

24. The method, as recited in claim 21, wherein in the step (a), said main circuit board has one or more holding holes provided therein, wherein the step (b) further comprising a step of extending and filling said holding hole with at least a portion of said molding portion to enhance a connection strength between said molding portion and said main circuit board.

25. The method, as recited in claim 22, wherein in the step (a), said main circuit board has one or more holding holes provided therein, wherein the step (b) further comprising a step of extending and filling said holding hole with at least a portion of said molding portion to enhance a connection strength between said molding portion and said main circuit board.

26. The method, as recited in claim 23, wherein in the step (a), said main circuit board has one or more holding holes provided therein, wherein the step (b) further comprising a step of extending and filling said holding hole with at least a portion of said molding portion to enhance a connection strength between said molding portion and said main circuit board.
